(19) United States
(12) Patent Application Publication
(10) Pub. No.: US 2024/0365495 A1
(43) Pub. Date: Oct. 31, 2024

(54) Display Device

(71) Applicant: LG Display Co., Ltd., Seoul (KR)

(72) Inventors: Jeong Jo Lee, Paju-si (KR); Han Seok Kim, Paju-si (KR)

(21) Appl. No.: 18/620,188

(22) Filed: Mar. 28, 2024

(30) Foreign Application Priority Data
Apr. 28, 2023 (KR) 10-2023-0056256

(51) Int. Cl. H05K 5/03

(52) U.S. Cl. CPC H05K 5/03

(57) ABSTRACT

A display device includes a display panel; a cover bottom disposed on a rear surface of the display panel; a plate bottom disposed to be in contact with the display panel at an opening of the cover bottom; a circuit board; a flexible film connecting the display panel and the circuit board through the opening; and a cover shield covering the circuit board, wherein the cover bottom includes a first grounding portion in contact with the plate bottom and a second grounding portion in contact with the cover shield, the cover shield includes a third grounding portion in contact with the circuit board, and at least one of the first grounding portion, the second grounding portion, and the third grounding portion is formed in a hemming structure.

### CROSS-REFERENCE TO RELATED APPLICATION

This application claims priority to and the benefit of Republic of Korea Patent Application No. 10-2023-0056256, filed Apr. 28, 2023, the disclosure of which is hereby incorporated by reference in its entirety.

### BACKGROUND

### 1. Field

An embodiment relates to a display device.

### 2. Discussion of Related Art

Organic light emitting display devices reproduce images by emitting light using an organic light emitting diode (OLED) placed in each pixel according to an input image signal. The organic light emitting display devices have a fast response speed and high luminous efficiency, high luminance, and wide viewing angle, and have an excellent contrast ratio and color reproducibility as it can express black grayscales in full black. No backlight unit is required for these organic light emitting display devices.

In recent years, the display devices that use an inorganic light-emitting device (a light emitting diode (LED)), as the light-emitting element of pixels have been attracted attention as the next generation of the display devices. Because the LEDs are made of inorganic materials, they do not require a separate encapsulation layer to protect the organic material from moisture, and they have an excellent reliability and a longer life than the OLEDs. The LEDs also have a fast light-up speed, excellent luminous efficiency, and are resistant to impact.

However, if static electricity is introduced into these display devices, the internal circuits of the display panel or the components of the display device may be damaged by the static electricity, and accordingly display devices need an electrostatic discharge (ESD) function capable of effectively discharging the static electricity introduced into the inside to the outside.

Rather, when a coating layer is formed on the cover members of the display device, there is a limitation implementing a grounding structure between the cover members due to the coating layer. For example, a grounding structure between cover members may be implemented by performing a separate processing process on the surface of the cover member, but there are ineffective problems in terms of productivity, such as an increase in process cost.

Accordingly, there is a need to develop a display device that implements a grounding structure while having a simple structure.

### SUMMARY

An embodiment is directed to providing a display device that prevents damage to internal circuits of a display panel or components of the display device by using grounding of cover members disposed on a rear surface of the display panel.

An embodiment is also directed to providing a display device that implements grounding of coated cover members using a hemming structure.

An embodiment is also directed to providing a display device that implements a uniform temperature distribution of a display panel using cover members.

Objectives to be solved by embodiments are not limited to the objectives described above, and objectives which are not described above will be clearly understood by those skilled in the art from the following descriptions.

According to an embodiment of the present disclosure, there is provided a display device including: a display panel; a cover bottom disposed on a rear surface of the display panel; a plate bottom disposed in contact with the display panel at an opening of the cover bottom; a circuit board; a flexible film connecting the display panel and the circuit board through the opening; and a cover shield covering the circuit board, wherein the cover bottom includes a first grounding portion in contact with the plate bottom and a second grounding portion in contact with the cover shield, and the cover shield includes a third grounding portion in contact with the circuit board, and wherein at least one of the first grounding portion, the second grounding portion, and the third grounding portion is formed in a hemming structure.

According to another embodiment of the present disclosure, there is provided a display device including: a display panel; a cover bottom disposed on a rear surface of the display panel; a plate bottom disposed in contact with the display panel at an opening of the cover bottom; a circuit board; and a flexible film connecting the display panel and the circuit board through the opening, wherein the cover bottom includes a cover body disposed to face the display panel, a cover coating layer formed on a rear surface of the cover body, and a first hemming portion formed by bending one side end of the cover body on which the cover coating layer is formed, and wherein the first hemming portion is in contact with a front surface of the plate bottom.

According to still another embodiment of the present disclosure, there is provided a display device including: a display panel; a cover bottom disposed on a rear surface of the display panel; a plate bottom disposed in contact with the display panel at an opening of the cover bottom; at least one pemnut disposed to protrude from the plate bottom (or disposed on the plate bottom to protrude toward the circuit board); a circuit board spaced apart from the plate bottom by the pemnut; a flexible film connecting the display panel and the circuit board through the opening; and a cover shield covering the circuit board, wherein the cover shield includes a shield body disposed to face the circuit board, a shield coating layer formed on a rear surface of the shield body, and a third hemming portion formed by bending one side end of the shield body on which the shield coating layer is formed, and wherein one surface of the third hemming portion is in contact with the circuit board.

According to an embodiment, grounding of cover members disposed on a rear surface of a display panel can be used to protect internal circuits of the display panel or components of a display device from external factors such as static electricity. Accordingly, since the lifetime of the display device is improved, enabling low-power driving of the production process in terms of reducing production energy.

According to an embodiment, productivity of the display device can be improved by implementing grounding of coated cover members using a hemming structure.

According to an embodiment, cover members can be used to implement a uniform temperature distribution on the display panel, thereby improving display quality of the display device.

According to an embodiment, a pemnut can be used to separate a circuit board from a display panel, thereby minimizing the influence on the display panel by heat generated from the circuit board. Accordingly, the lifetime of the display panel can be improved.

According to an embodiment, an air gap formed between a plate bottom and a display panel and an air gap formed between a pemnut and the display panel are used so that the influence on the display panel by the heat generated from the circuit board can be minimized. Accordingly, the lifetime of the display panel can be improved.

An embodiment of the present invention discloses a display device including a display panel, a circuit board, a flexible film, and cover members disposed on one side of the display panel. Accordingly, the embodiment may uniformly implement a temperature distribution of the display panel using a grounding structure implemented through the cover members, a heat dissipation structure, and air gaps formed in the cover members while preventing damage to internal circuits of the display panel or components of the display device.

Various useful advantages and effects of the embodiments are not limited to the above-described contents, and effects which are not described above will be clearly understood by those skilled in the art from the following descriptions.

### BRIEF DESCRIPTION OF THE DRAWINGS

The above and other objects, features, and advantages of the present disclosure will become more apparent to those of ordinary skill in the art by describing exemplary embodiments thereof in detail with reference to the attached drawings, in which:

FIG. 1 is a block diagram schematically showing a configuration of a display device according to one embodiment of the present specification;

FIG. 2 is a partial cross-sectional view showing a pad portion and a side wiring disposed on the outermost portion of a display panel according to one embodiment of the present specification;

FIG. 3 is a perspective view showing a tiled display device according to one embodiment of the present specification;

FIG. 4 is a block diagram schematically showing control boards connected to a plurality of printed circuit boards and a system board connected to the control boards;

FIG. 5 is a plan view schematically showing a planar structure of a display panel according to one embodiment of the present specification;

FIG. 6 is a cross-sectional view showing in detail a cross-sectional structure of a display panel according to one embodiment of the present specification;

FIG. 7 is a perspective view showing a display device according to one embodiment of the present specification;

FIG. 8 is an exploded perspective view showing a display device according to one embodiment of the present specification;

FIG. 9 is a plan view showing a display device according to an embodiment of the present specification;

FIG. 10 is a cross-sectional view showing a cross section taken along line A-A′ of FIG. 9 according to an embodiment of the present specification;

FIG. 11 is a partial enlarged view of an area B of FIG. 10 according to an embodiment of the present specification;

FIG. 12 is a diagram showing a movement of heat in a display device according to an embodiment of the present specification;

FIG. 13 is a perspective view showing a cover bottom disposed on a display device according to an embodiment of the present specification;

FIG. 14 is a perspective view showing an arrangement relationship between a plate bottom and a pemnut disposed in a display device according to an embodiment of the present specification;

FIG. 15 is a perspective view showing a circuit board and gasket disposed in a display device according to an embodiment of the present specification;

FIG. 16 is a perspective view showing a pemnut disposed in a display device according to an embodiment of the present specification;

FIG. 17 is a front view showing a pemnut disposed in a display device according to an embodiment of the present specification;

FIG. 18 is a perspective view showing a cover shield disposed on a display device according to an embodiment of the present specification;

FIG. 19 is a diagram showing a cross section of a gasket disposed in a display device according to an embodiment of the present specification;

FIG. 20 is a perspective view showing a state in which display devices are fixed to a frame according to an embodiment of the present specification;

FIG. 21 is a partially enlarged view of an area Q1 in FIG. 20 according to an embodiment of the present specification; and

FIG. 22 is a cross-sectional view showing a cross section taken along line B-B′ of FIG. 21 according to an embodiment of the present specification.

### DETAILED DESCRIPTION

The advantages and features of the present disclosure and methods for accomplishing the same will be more clearly understood from embodiments described below with reference to the accompanying drawings. However, the present disclosure is not limited to the following embodiments but may be implemented in various different forms. Rather, the present embodiments will make the disclosure of the present disclosure complete and allow those skilled in the art to completely comprehend the scope of the present disclosure. The present disclosure is only defined within the scope of the accompanying claims.

In describing the present disclosure, detailed descriptions of known related technologies may be omitted so as not to unnecessarily obscure the subject matter of the present disclosure.

The terms such as “comprising”, “including”, and “having” used herein are generally intended to allow other components to be added unless the terms are used with the term “only”. References to the singular shall be construed to include the plural unless expressly stated otherwise.

When describing a positional or interconnected relationship between two components using the terms such as “on top of”, “above”, “below”, “next to”, “connect or couple with”, “crossing”, “intersecting” etc., one or more other components may be interposed between them unless “immediately” or “directly” is used.

When describing a temporal contextual relationship is described using the terms such as “after”, “following”, “next to” or “before”, it may not be continuous on a time scale unless “immediately” or “directly” is used.

The terms “first”, “second” and the like may be used to distinguish components from each other, but the functions or structures of the components are not limited by ordinal numbers or component names in front of the components.

The following embodiments may be combined or associated with each other in whole or in part, and various types of interlocking and driving are technically possible. The embodiments may be implemented independently of each other or together in an interrelated relationship.

Terms used in the embodiments of the disclosure (including technical and scientific terms) are to be construed as they would be commonly understood by one of ordinary skill in the art to which the invention belongs, unless otherwise specifically defined and described, and commonly used terms, such as dictionary defined terms, are to be construed in light of their contextual meaning in the relevant art.

Hereinafter, embodiments of the present disclosure will be described in detail with reference to the accompanying drawings.

In the recent information society, display devices have become increasingly important as visual information transmission media, and they are being improved to meet requirements such as low power consumption, thinness, weight reduction, high definition, and high efficiency.

A display device according to one an embodiment of the present disclosure may prevent or at least reduce damage to internal circuits of a display panel or components of the display device by using grounding of cover members disposed on a rear surface of the display panel, thereby improving the lifetime of the display panel. Accordingly, it enables greenhouse gas reduction in terms of reducing production energy.

In addition, the present disclosure may provide a compact display device while implementing a stable grounding of the display device by presenting at least one grounding structure using a hemming structure. For example, since the display device can use a hemming structure, a separate processing process for forming a grounding structure on the cover members can be omitted.

A display device according to one embodiment of the present disclosure may improve the lifetime of a display panel by minimizing or at least reducing a temperature difference for each area of the display panel and uniformly implementing a temperature distribution of the display panel. Accordingly, it enables greenhouse gas reduction in terms of reducing production energy.

In this case, the display device presents a radiant heat structure using a cover bottom and a plate bottom, so that a uniform temperature distribution of the display panel may be realized while minimizing or at least reducing a temperature difference for each area of the display panel disposed in the display device.

In addition, the display device can reduce the influence on the display panel by heat generated from a circuit board through a structure that separates the display panel from the circuit board.

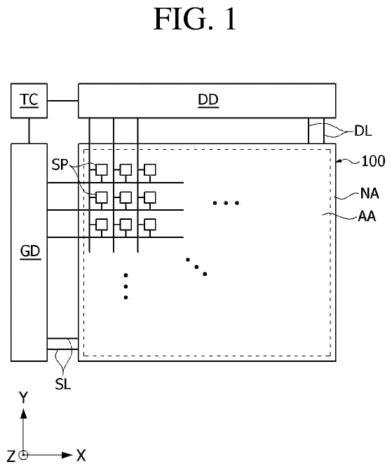

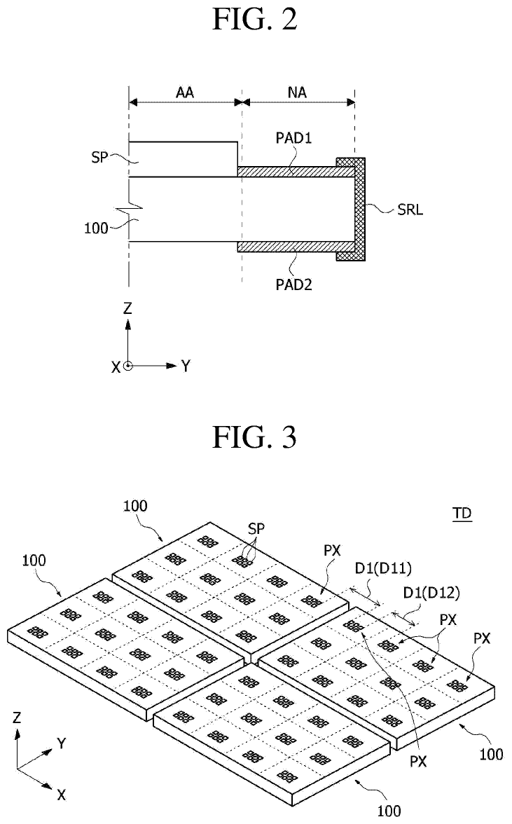

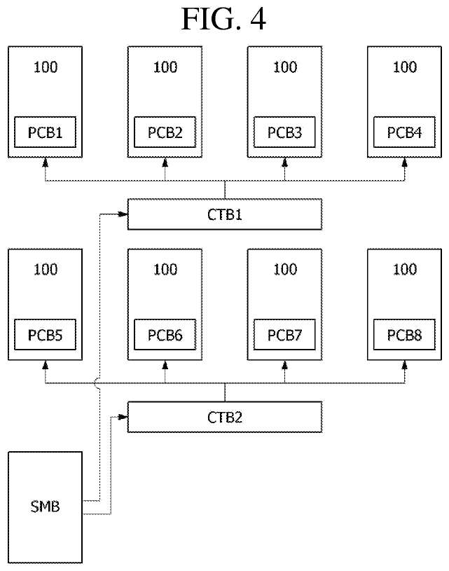

FIG. 1 is a block diagram schematically showing a configuration of a display device according to one embodiment of the present specification; FIG. 2 is a partial cross-sectional view showing a pad portion and a side wiring disposed on the outermost portion of a display panel according to one embodiment of the present specification; FIG. 3 is a perspective view showing a tiled display device according to one embodiment of the present specification; and FIG. 4 is a block diagram schematically showing control boards connected to a plurality of printed circuit boards and a system board connected to the control boards.

Referring to FIG. 1, the display device includes a display panel 100 in which a plurality of pixels are arranged in a display area AA, and a driving circuit that drives the pixels.

The display panel 100 may be a panel having a rectangular structure with a length in the X-axis direction, a width in the Y-axis direction, and a thickness in the Z-axis direction. The pixels include a plurality of sub-pixels SP with different colors. The driving circuit includes a data driver DD, a gate driver GD, and a timing controller TC that controls the gate driver GD and the data driver DD. The display area AA on which an input image is displayed on the display panel 100 may be a screen visible from the front surface of the display panel 100. Here, the width and length of the display panel 100 may be set to various design values depending on the application fields of the display device. In addition, the X-axis direction may mean a longitudinal direction or a horizontal direction, the Y-axis direction may mean a width direction or a vertical direction, and the Z-axis direction may mean an up-down direction or a thickness direction. In addition, the X-axis direction, Y-axis direction, and Z-axis direction may be perpendicular to each other, but may also mean different directions that are not perpendicular to each other. Accordingly, each of the X-axis direction, Y-axis direction, and Z-axis direction may be described as one of a first direction, a second direction, and a third direction. In addition, the plane extending in the X-axis direction and the Y-axis direction may mean a horizontal plane.

The input image is displayed on the subpixels SP disposed in the display area AA of the display panel 100. Each of the subpixels SP includes a light emitting element and a pixel circuit that drives the light emitting element. The light emitting element may be a light emitting diode (LED) or a micro light emitting diode (micro LED).

On the display panel 100, a plurality of scan wirings (in other words, scan lines) SL and a plurality of data wirings (in other words, data lines) DL are arranged to cross each other. Each of the subpixels SP is connected to a scan wiring SL and a data wiring DL. Power supply wirings (in other words, power supply lines) omitted in FIG. 1 may be connected to each of the subpixels SP. In a display panel 100, a non-display area NA may be disposed outside the display area AA.

The gate driver GD supplies scan signals to the scan wirings SL in response to a gate control signal provided by the timing controller TC. The gate driver GD may be disposed at least in the non-display area NA of the display panel 100, as shown in FIG. 1, or disposed in the display area AA.

The data driver DD converts the image data received from the timing controller TC into a reference compensation voltage and outputs a data voltage in response to a data control signal provided by the timing controller TC. The data voltage output from the data driver DD is supplied to the data wirings DL.

The timing controller TC aligns image data input from the outside and supplies the aligned image data to the data driver DD. The timing controller TC may generate gate control signals and data control signals based on timing signals synchronized with input image signals, for example, dot clock signals, data enable signals, and horizontal/vertical synchronization signals. The timing controller TC supplies the gate control signals to the gate driver GD and the data control signals to the data driver DD to control the timing of the operation of the gate driver GD and the data driver DD.

The non-display area NA may have link wirings (in other words, link lines) and pad electrodes disposed therein to transmit signals to the subpixels SP in the display area AA. Furthermore, one or more of a gate driver IC in which circuits for the gate driver GD are integrated and a data driver IC in which circuits for the data driver DD are integrated may be disposed in the non-display area NA. The non-display area NA may be located on the rear surface of the display panel 100, i.e., on the rear surface where there are no subpixels SP, or it may be minimized to the extent that it is invisible when an image is displayed on the display panel 100.

The drivers such as the gate driver GD, the data driver DD, and the timing controller TC may be connected to the display panel 100 in a variety of ways. For example, the gate driver GD may be disposed in a gate in panel (GIP) fashion in the non-display area NA, or in a gate in active area (GIA) fashion between subpixels SP in the display area AA. For example, the data driver DD and the timing controller TC may be formed on separate flexible films and printed circuit boards (hereinafter referred to as “PCB”), and the data driver DD and the timing controller TC may be electrically connected to the display panel 100 by bonding the flexible films and the PCBs to pad electrodes formed on the non-display area NA of the display panel 100.

A side wiring (in other words, side line) for connecting the signal wirings (in other words, signal lines) on the front surface of the display panel 100 to the pad electrodes on the rear surface of the display panel 100 may be formed on the outermost side surface of the display panel 100. Such a method of providing an electrical connection between the front surface and the rear surface of the display panel 100 via the side wiring may maximally minimize the non-display area NA visible on the front surface of the display panel 100. In FIG. 2, “SRL” denotes this side wiring. When the gate driver GD, the data driver DD, and the timing controller TC are connected to the display panel 100 in the above manner, a screen without a bezel may be substantially realized.

Referring to FIG. 2, a plurality of pad electrodes are disposed in the non-display area NA of the display panel 100 to transmit various signals to the subpixels SP. For example, a first pad electrode PAD1, which transmits signals to the subpixels SP, may be disposed in the non-display area NA located at the front surface of the display panel 100. A second pad electrode PAD2, which is electrically connected to circuit components such as the flexible films and the PCBs, is disposed in the non-display area NA at the rear surface of the display panel 100. Only the pad area in which the first pad electrode PAD1 is located is disposed in the non-display area NA located at the front outermost portion of the display panel 100 on which an image is displayed, thereby minimizing the size of the non-display area.

Various signal wirings associated with the subpixels SP, such as the scan wiring SL or the data wiring DL, may extend into the non-display area NA and be electrically connected to the first pad electrode PAD1.

The display panel 100 may include the side wiring SRL disposed on the outermost side surface of the display panel 100. The side wiring SRL may electrically connect the first pad electrode PAD1 disposed on the front outermost portion of the display panel 100 and the second pad electrode PAD2 disposed on the rear outermost portion of the display panel 100 while traversing the side surface of the display panel 100. The signals output from the circuit components disposed at the rear surface of the display panel 100 may be transmitted to the subpixels SP within the display area AA via the second pad electrode PAD2, the side wiring SRL, and the first pad electrode PAD1. Accordingly, the area of the non-display area NA on the front surface of the display panel 100 may be minimized by forming a signal transmission path traversing the front, side, and rear surfaces at the outermost portion of the display panel 100.

As shown in FIG. 3, a plurality of display modules may be combined on a plane to be implemented as a large-screen tiled display device. Each of the display modules may be implemented as a single display device, and a large-screen tiled display device may be implemented through a combination of a plurality of display modules. Each of the display modules may include a single sheet of a display panel 100, a driving circuit of the display panel 100, and circuit components and module cover members coupled to a rear surface of the display panel 100.

Referring to FIG. 3, a large-screen tiled display device TD includes a plurality of display modules arranged on the XY plane. Each of the display modules includes a display panel 100 that reproduces an input image. When the non-display area NA is minimized at the outermost portion of the front surface of each of the display panels 100, the tiled display device TD may reproduce a large screen image with no visible seams between neighboring display panels 100.

In the tiled display device TD, the outermost pixels PX of two display panels 100 arranged adjacent to each other are arranged to have a predetermined distance D1. In addition, neighboring pixels PX within the display area AA of the display panel 100 are also arranged to have the distance D1. As a result, the distance D1 between pixels PX is the same throughout the large screen display area of the tiled display device TD, so the seam area is not visible. Here, reference numeral D11 in FIG. 3 may indicate the distance between the outermost pixels PX of two display panels 100 arranged adjacent to each other in the tiled display device TD, and reference numeral D12 may indicate the distance between neighboring pixels PX within the display area AA. In addition, the distance indicated by D11 and the distance indicated by D12 may be the same, but they may also be different only if the seam area is not visible. In addition, the distance D1 may be referred to as a first distance.

In the tiled display device TD, a plurality of display modules may share one timing controller TC. A host system may be connected to a plurality of timing controllers TC to transmit image signals to be reproduced on all of display panels 100 implementing the large screen of the tiled display device TD to the timing controllers TC, and to synchronize the timing controllers TC.

Referring to FIG. 4, each of the display modules may include a single sheet of a display panel 100 and one PCB. A system board SMB is connected to M (M is an integer greater than or equal to 2) control boards CTB1, CTB2. Each of the control boards CTB1, CTB2 is connected to N (N is an integer greater than M) PCBs.

A first control board CTB1 may be connected to the PCBs of first to fourth display modules PCB1 to PCB4 via flexible films or cables. A second control board CTB2 may be connected to the PCBs of a fifth to eighth display modules PCB5 through PCB8 via flexible films or cables. The system board SMB may be connected to the first and second control boards CTB1, CTB2 via flexible films or cables.

The system board SMB may be a main board of the host system. The system board SMB includes a user interface port to receive user input, an external interface port connected to external devices, a communication module to access various communication protocols, a processor to process multi-media signals, a central processing unit (CPU), and a main power supply. The system board SMB sends an input image signal and a timing signal to the control boards CTB1, TB2. The timing controllers TC mounted on the control boards CTB1, CTB2 transmits the received image signal to the data driver DD and controls the data driver DD and the gate driver GD based on the timing signal. The driving circuits DD, GD for the N display modules write image data to the corresponding display panels 100 under the control of one timing controller TC.

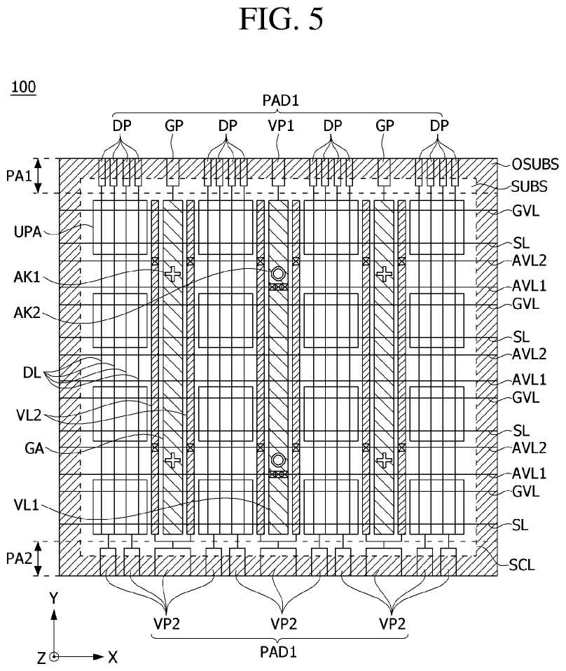

FIG. 5 is a plan view schematically showing a planar structure of a display panel according to one embodiment of the present specification.

Referring to FIG. 5, the display panel 100 includes a substrate SUBS on which a pixel array and a circuit for gate driver GD are arranged.

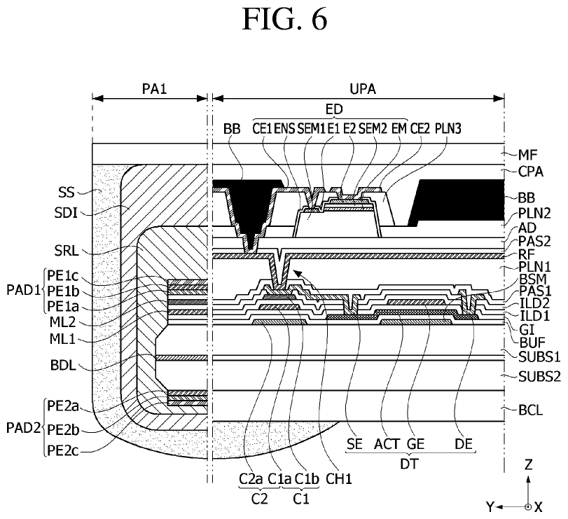

The substrate SUBS may be an insulating substrate that supports components disposed on the display device. The substrate SUBS may have a stacked structure of first and second substrates SUBS1, SUBS2, as shown in FIG. 6. Each of the first and second substrates SUBS1, SUBS2 may be fabricated as a glass, polymer resin, or plastic substrate. Each of the first and second substrates SUBS1, SUBS2 may be made as a flexible substrate that has flexibility, but is not limited thereto.

On one surface (or front surface) of the substrate SUBS, a display area AA may include a plurality of pixel areas UPA, a plurality of gate driving areas GA, and a plurality of pad areas PA1, PA2. One or more pixels PX may be disposed in each of the pixel areas UPA. The pixel areas UPA may be arranged along a plurality of row lines and a plurality of column lines. Each of the pixels PX includes a plurality of subpixels SP with different colors. Each of the subpixels SP may emit light independently, including light emitting elements and pixel circuit. The subpixels SP may include, but are not limited to, red subpixels, blue subpixels, and green subpixels.

The plurality of gate driving areas GA includes circuits for gate drivers GD. The gate driving areas GA may be formed along a row direction and/or a column direction between the plurality of pixel areas UPA. A gate driver GD formed in a gate driving area GA may provide a scan signal to a plurality of scan wrings SL.

A first pad area PA1 includes a plurality of first pad electrodes PAD1 disposed on the outermost front surface of one side (or upper side) of the display panel 100. The first pad electrodes PAD1 may transmit various signals to various wirings extending in the column direction from the display area AA. The first pad electrodes PAD1 include data pads DP connected to data wiring DL to delivery data voltage from the data driver DD to the data wiring DL, and gate pads GP connected to the gate driver GD to transmit clock signals, start signals, gate low voltage, gate high voltage, etc. for driving the gate driver GD to the gate driver GD. The clock signals, start signals, gate low voltages, gate high voltages, etc. for driving the gate driver GD may be generated from the timing controller TC and applied to the gate pads GP through a level shifter and a PCB. The first pad electrodes PAD1 may include a plurality of power wirings to which a direct current voltage (or a constant voltage) is applied.

A second pad area PA2 includes a plurality of second pad electrodes PAD2 disposed on the outermost front surface of the other side (or lower side) of the display panel 100. The second pad area PA2 may include a plurality of low-potential power supply pads VP2.

A DC voltage to be applied to the power wirings may be output from a power supply circuit omitted in the drawings, and may be applied to power supply pads VP1 and VP2 connected to the power wirings through the PCB. The power supply circuit may be is a DC-DC converter disposed on a PCB or control board CTB1, CTB2 disposed on the rear surface of the display panel 100 to convert a DC input voltage from the main power supply into a DC voltage suitable for driving the display panel 100.

The power pads VP1, VP2 connected to the power wirings may include a plurality of high-potential power pads VP1 disposed on the first pad area PA1 to deliver high-potential power voltages to high-potential power wirings VL1, and a plurality of low-potential power pads VP2 disposed on the second pad area PA2 to deliver low-potential power voltages to low-potential power wirings VL2.

The data pads DP, which are connected one-to-one to the data wirings DL, may have a relatively narrow width, while the power pads VP1, VP2 and the gate pads GP may have a relatively wide width. The low-potential power pads VP2 may have a wider width compared to the high-potential power pads VP1. The widths of the pads DP, GP, VP1, and VP2 are not limited to those shown in FIG. 5.

In order to minimize or at least reduce the outermost non-display area NA of the display panel 100, the substrate SUBS is cut along a scribing line SCL after the pixel array, wirings, and pads are formed on the front surface of the substrate SUBS of the display panel 100. Accordingly, a portion outside the scribing OSUBS may be removed to provide the substrate SUBS. After the scribing process, rough edges on the outermost side surface of the substrate SUBS may be grounded or laser trimmed. This will leave the short pad electrodes PAD1, PAD2 on the outermost front surface of the substrate SUBS which has been reduced in size.

The data wirings DL may extend in the column direction Y on the substrate SUBS and overlap the pixel areas UPA. The data wirings DL supply the data voltages to the respective pixel circuits of the subpixels SP. The scan wirings SL may extend in the row direction X on the substrate SUBS of the display panel 100 and overlap the pixel areas UPA and the gate driving areas GA. The scan wirings SL may supply the scan signals from the gate driver GD across the pixel areas UPA and the gate driving areas GA to the respective pixel circuits of the subpixels SP.

The high-potential power supply wirings VL1 extend in the column direction (Y direction), and are connected in a mesh structure to auxiliary high-potential power supply wirings AVL1, at least one of which extends in the row direction (X direction). The auxiliary high-potential power supply wirings AVL1 are connected to the subpixels SP arranged in the row direction X. Therefore, the high-potential power supply voltages applied to the high-potential power supply wirings VL1 may be delivered to the subpixels SP via the auxiliary high-potential power supply wirings AVL1.

The low-potential power supply wirings VL2 extend in the column direction (Y direction), and are connected in a mesh structure to the auxiliary low-potential power supply wiring AVL2, at least one of which extends in the row direction (X direction). The auxiliary low-potential power supply wiring AVL2 is connected to the subpixels SP arranged in the row direction X. Therefore, the subpixels SP are connected to the auxiliary low-potential power supply wirings AVL2 to which the low-potential power supply voltage is applied.

The mesh structure of the power wirings may allow the resistance of the power wirings to be reduced, which may improve the voltage drop of the high-potential power supply voltage and the deviation of the power supply voltage within the display area AA.

A plurality of gate driving wirings GVL extending in the row direction is disposed on the substrate SUBS of the display panel 100. The plurality of gate driving wirings GVL carries signals necessary to drive the gate drivers GD disposed in the gate driving area GA, such as clock signals, start signals, gate high voltages, gate low voltages, etc.

The substrate SUBS of the display panel 100 may include one or more alignment keys AK1, AK2 disposed between the pixel areas UPA. The alignment keys AK1, AK2 may be used for alignment in the manufacturing process of the display panel 100. A first alignment key AK1 may be disposed in the gate driving area GA. The first alignment key AK1 may be used to check the aligned position of each of the light emitting elements. The first alignment key AK1 may be formed in a cross pattern, but is not limited thereto. A second alignment key AK2 may overlap the high-potential power supply wiring VL1. The high-potential power supply wiring VL1 includes a hole formed at a position overlapping with the second alignment key AK2, thereby distinguishing the second alignment key AK2 from the high-potential power supply wiring VL1. The second alignment key AK2 may be used to align the display panel 100 and a donor substrate. The donor substrate is an intermediate medium for mounting a light emitting element on the substrate SUBS of the display panel 100. A plurality of light emitting elements fabricated on a semiconductor wafer may be attached to the donor substrate and transported, and the light emitting elements attached on the donor substrate may be transferred onto the substrate SUBS. The second alignment key AK2 may be formed in a circular or ring pattern, but is not limited thereto.

FIG. 6 is a cross-sectional view showing a cross-sectional structure of a display panel according to one embodiment of the present specification.

Referring to FIG. 6, a pixel circuit for driving light emitting elements ED is disposed in each of a plurality of sub-pixels SP on a first substrate SUBS1. The pixel circuit may include a plurality of thin film transistors and one or more capacitors. For convenience of explanation, a driving transistor DT, a first capacitor C1, and a second capacitor C2 used as a pixel circuit are shown in FIG. 6, but the display panel 100 may further include other circuit elements.

A pattern of a first metal layer may be disposed on the first substrate SUBS1. The pattern of the first metal layer may include a light shielding layer BSM. The light shielding layer BSM may block light from entering an active layer ACT of the driving transistor DT to minimize or at least reduce leakage current. The light shielding layer BSM may be formed of an opaque conductive material, e.g., a metal such as copper (Cu), aluminum (Al), molybdenum (Mo), nickel (Ni), titanium (Ti), chromium (Cr), an alloy of these metals, or a multilayer of metal layers.

A buffer layer BUF may be disposed on the light shielding layer BSM. The buffer layer BUF may block penetration of moisture or impurities through the first substrate SUBS1. The buffer layer BUF may be formed of silicon oxide (SiOx), silicon nitride (SiNx), or a multilayer of insulating layers.

The driving transistor DT including an active layer ACT, a gate electrode GE, a source electrode SE, and a drain electrode DE may be disposed on the buffer layer BUF.

The active layer ACT may be made of a semiconductor material such as, but not limited to, an oxide semiconductor, amorphous silicon, or polysilicon. A gate insulating layer GI electrically insulates the active layer ACT and the gate electrode GE of the driving transistor DT. The gate insulating layer GI may be formed of silicon oxide (SiOx), silicon nitride (SiNx), or a multilayer of insulating layers.

A pattern of a second metal layer may be disposed on a gate insulating layer GI. The pattern of the second metal layer may include the gate electrode GE of the driving transistor DT. The second metal layer may be formed of copper (Cu), aluminum (Al), molybdenum (Mo), nickel (Ni), titanium (Ti), chromium (Cr), or a multilayer of metal layers.

A first interlayer insulating layer ILD1 and a second interlayer insulating layer ILD2 are disposed on the gate electrode GE. In the first interlayer insulating layer ILD1 and the second interlayer insulating layer ILD2, contact holes for connecting each of the source electrode SE and the drain electrode DE of the driving transistor DT to the active layer ACT are formed. Each of the first interlayer insulating layer ILD1 and the second interlayer insulating layer ILD2 may be formed of silicon oxide (SiOx), silicon nitride (SiNx), or a multiple layer of insulating layers.

A pattern of a third metal layer may be disposed on a second interlayer insulating layer ILD2. The pattern of the third metal layer may include the source electrode SE and the drain electrode DE overlapping the active layer ACT and connected to the active layer ACT through the contact holes penetrating the interlayer insulating layers ILD1 and ILD2. The source electrode SE may be connected to the capacitors C1, C2 and a first electrode E1 of the light emitting element ED. The third metal layer may be formed of copper (Cu), aluminum (Al), molybdenum (Mo), nickel (Ni), titanium (Ti), chromium (Cr), or a multilayer of metal layers.

The first capacitor C1 includes a first capacitor electrode C1a and a second capacitor electrode C1b. The first capacitor electrode C1a may be formed as the pattern of the second metal layer disposed on the gate insulating layer GI. The second capacitor electrode C1b is formed in a pattern of a fourth metal layer disposed on the first interlayer insulating layer ILD1 to overlap the first capacitor electrode C1a with the first interlayer insulating layer ILD1 interposed therebetween. The second capacitor electrode C1b may be connected to the source electrode SE of the driving transistor DT. The fourth metal layer may be formed of copper (Cu), aluminum (Al), molybdenum (Mo), nickel (Ni), titanium (Ti), chromium (Cr), or a multilayer of metal layers.

The second capacitor C2 includes a third capacitor electrode C2a that overlaps the first capacitor electrode C1a with the buffer layer BUF and the gate insulating layer GI interposed therebetween. The third capacitor electrode C2a may be formed as the pattern of the second metal layer disposed on the gate insulating layer SUBS1.

The second capacitor C2 is electrically connected between the source electrode SE of the driving transistor DT and the light emitting element ED to increase the capacitance of the light emitting element ED, which may increase the brightness when the light-emitting element ED emits light.

A first passivation layer PAS1 covers the pattern of the third metal layer and the second interlayer insulating layer ILD2. The first passivation layer PAS1 may be formed of silicon oxide (SiOx), silicon nitride (SiNx), or a multilayer of insulating layers.

A first planarization layer PLN1 is disposed on the first passivation layer PAS1. The first planarization layer PLN1 covers the first passivation layer PAS1 to flatten a surface on which the light emitting element is disposed. The first planarization layer PLN1 may be a thick single-layer or multilayer of organic insulating layers made of benzocyclobutene or acryl-based organic material.

A pattern of a fifth metal layer may be disposed on the first planarization layer PLN1. The pattern of the fifth metal layer may include a light reflective layer RF. The reflective layer RF may reflect light from the light emitting element ED toward the front of the display panel 100 to increase light efficiency, and may be used as an electrode to connect the light emitting element ED to the pixel circuit or the power supply wirings. The reflective layer RF may be electrically connected to the source electrode SE of the driving transistor DT and the first capacitor C1 through the contact hole CHI penetrating the first planarization layer PLN1 and the first passivation layer PAS1. In addition, the reflective layer RF may be electrically connected to the first electrode E1 of the light-emitting element ED through a first connection electrode CE1, or may be connected to a second electrode E2 of the light-emitting element ED and a high-potential power supply wiring VL1. The fifth metal layer may be formed of a transparent electrode material such as silver (Ag), aluminum (Al), molybdenum (Mo), titanium (Ti), indium tin oxide (ITO), or a multilayer of metal layers.

A second passivation layer PAS2 covers the pattern of the fifth metal layer and the first planarization layer PLN1. The second passivation layer PAS2 may be formed of silicon oxide (SiOx), silicon nitride (SiNx), or a multilayer of insulating layers.

An adhesive layer AD may be disposed on the second passivation layer PAS2 to secure the light emitting element ED. The adhesive layer AD may be formed of a photocurable resin that can be cured by light. The adhesive layer AD may be formed of, but is not limited to, an acrylic-based material containing a photosensitive agent. The adhesion layer AD may be formed on the front surface of the first substrate SUBS1 except for the pad areas PA1 in which the first pad electrode PAD1 is to be disposed.

A light emitting element ED of each of the sub-pixels SP may be disposed on the adhesive layer AD. Light emitting elements ED may emit light by current from the driving transistor DT. The light emitting elements ED may include red light emitting elements ED, green light emitting elements ED, and blue light emitting elements ED. The light emitting elements ED may be a light emitting diode (LED) or a micro LED.

Each of the light emitting elements ED includes a first semiconductor pattern SEM1, a light emitting layer EM, a second semiconductor pattern SEM2, a first electrode E1, and a second electrode E2.

The first semiconductor pattern SEM1 is disposed on the adhesive layer AD, and the second semiconductor pattern SEM2 is disposed on the first semiconductor pattern SEM1. The first semiconductor pattern SEM1 and the second semiconductor pattern SEM2 may be formed as semiconductor patterns obtained by doping n-type and p-type impurities into a semiconductor material. For example, each of the first semiconductor pattern SEM1 and the second semiconductor pattern SEM2 may be a doped layer with n-type or p-type impurities in materials such as gallium nitride (GaN), indium aluminum phosphide (InAlP), and gallium arsenide (GaAs), etc. In addition, the p-type impurities may be magnesium, zinc (Zn), beryllium (Be), etc., and the n-type impurities may be silicon (Si), germanium, tin (Sn), etc., but are not limited thereto.

A light emitting layer EM is disposed between the first semiconductor pattern SEM1 and the second semiconductor pattern SEM2. The light emitting layer EM may emit light by receiving holes and electrons from the first semiconductor pattern SEM1 and the second semiconductor pattern SEM2. The light emitting layer EM may have a single-layer or multi-quantum well (MQW) structure and may be formed of, for example, indium gallium nitride (InGaN) or gallium nitride (GaN).

The first electrode E1 is disposed on the first semiconductor pattern SEM1. The first electrode E1 electrically connects the first semiconductor pattern SEM1 with the driving transistor DT. The first semiconductor pattern SEM1 may be formed of a semiconductor layer doped with n-type impurities. The first electrode E1 may be an anode electrode of the light emitting element ED disposed on the first semiconductor pattern SEM1 and electrically connected to the driving transistor DT and the capacitors C1, C2 via the reflection layer RF. The first electrode E1 may be disposed on the top surface of the first semiconductor pattern SEM1. The first electrode E1 may be formed of a conductive material, for example, a transparent conductive material such as indium tin oxide (ITO) or indium zinc oxide (IZO), or an opaque conductive material such as titanium (Ti), gold (Au), silver (Ag), copper (Cu), or an alloy thereof.

The second electrode E2 is disposed on the second semiconductor pattern SEM2. The second electrode E2 electrically connects the high potential power supply line VL1 and the second semiconductor pattern SEM2. The second semiconductor pattern SEM2 may be formed as a semiconductor layer doped with p-type impurities. The second electrode E2 may be a cathode electrode of the light emitting element ED. The second electrode E2 may be formed of a conductive material, for example, a transparent conductive material such as indium tin oxide (ITO) or indium zinc oxide (IZO), or an opaque conductive material such as titanium (Ti), gold (Au), silver (Ag), copper (Cu), or an alloy thereof.

The light emitting element ED may include a sealing layer ENS. The sealing layer ENS covers the semiconductor patterns SEM1 and SEM2 and electrodes E1 and E2 to protect the light emitting element ED. The sealing layer ENS and a third planarization layer PLN3 include contact holes exposing the first electrode E1 and the second electrode E2. A first connection electrode CE1 is connected to the reflection layer RF through a first contact hole penetrating the sealing layer ENS and the third planarization layer PLN3. A second connection electrode CE2 is connected to the second electrode E2 through a second contact hole penetrating the sealing layer ENS and the third planarization layer PLN3. Meanwhile, a portion of a side surface of the first semiconductor pattern SEM1 may be exposed without being covered by the sealing layer ENS.

The second planarization layer PLN2 and the third planarization layer PLN3 may cover the adhesive layer AD and the light emitting element ED. The second planarization layer PLN2 is in contact with a lower end of the side surface of the light emitting element ED to secure the light emitting element ED. The third planarization layer PLN3 covers the light emitting element ED on the second planarization layer PLN2. The third planarization layer PLN3 includes contact holes exposing the first electrode E1 and the second electrode E2 of the light emitting element ED. The second planarization layer PLN2 and the third planarization layer PLN3 may be formed of a single layer or a multilayer of organic insulating materials, for example, photoresists or acryl-based organic materials.

A pattern of a sixth metal layer may be disposed on the third planarization layer PLN3. The sixth metal layer includes the first connection electrode CE1 and the second connection electrode CE2. The first connection electrode CE1 electrically connects the first electrode E1 of the light emitting element ED and the reflective layer RF. The first connection electrode CE1 may be connected to the first electrode E1 of the light emitting element ED through a contact hole penetrating the insulating layers PLN3 and ENS, and may be connected to the reflective layer RF through a contact hole penetrating the insulating layers PAS2, AD, PLN2, and PLN3.

The second connection electrode CE2 is connected to the second electrode E2 of the light emitting element ED through a contact hole penetrating the insulating layers PLN3 and ENS. The second connection electrode CE2 may be connected to the low-potential power wiring VL2.

A bank pattern BB may be disposed on the second planarization layer PLN2. The bank pattern BB may be spaced apart from the light emitting element ED at regular intervals. The bank pattern BB may cover a portion of the first connection electrode CE1 present in a contact hole penetrating the insulating layers PLN2 and PLN3. The bank pattern BB may reduce color mixing between subpixels SP by preventing optical crosstalk between subpixels SP. To this end, the bank pattern BB may be formed of black resin, but is not limited thereto.

A first protective layer CPA may cover the patterns CE1 and CE2 of the sixth metal layer, the bank pattern BB, the second planarization layer PLN2, and the third planarization layer PLN3. The first protective layer CPA may be formed of a single layer or a multilayer of insulating layers of translucent epoxy, silicon oxide (SiOx), or silicon nitride (SiNx).

Each of the first pad electrodes PAD1 disposed in the pad area PA1 of the first substrate SUBS1 may have a multilayer structure of metal layers. For example, each of the first pad electrodes PAD1 may include a first pad metal layer PE1a, a second pad metal layer PE1b, and a third pad metal layer PE1c stacked on the outermost front surface of the first substrate SUBS1.

The pattern of the third metal layer disposed on the second interlayer insulating layer ILD2 may further include a first pad metal layer PE1a. The first pad metal layer PE1a may be formed of the same metal as the source electrode SE and drain electrode DE of the driving transistor DT, such as copper (Cu), aluminum (Al), molybdenum (Mo), nickel (Ni), titanium (Ti), chromium (Cr), or a multilayer of metal layers.

The pattern of the fifth metal layer disposed on the first planarization layer PLN1 may further include a second pad metal layer PE1b. The second pad metal layer PE1b may be formed of the same metal as the reflective layer RF, for example, silver (Ag), aluminum (Al), molybdenum (Mo), or a multilayer of metal layers.

The pattern of the sixth metal layer disposed on the third planarization layer PLN3 may further include the third pad metal layer PE1c. The third pad metal layer PE1c may be formed of the same conductive material as the first connection electrode CE1 and the second connection electrode CE2, for example, a transparent conductive material such as indium tin oxide (ITO) or indium zinc oxide (IZO), or a multilayer of metal layers, etc.

A first metal layer ML1 and a second metal layer ML2 and a plurality of insulating layers may be disposed under the first pad electrodes PAD1. By disposing the first metal layer ML1, the second metal layer ML2, and the plurality of insulating layers under the first pad electrode PAD1, a step difference of the first pad electrodes PAD1 may be adjusted. For example, a buffer layer BUF, a gate insulating layer GI, a first metal layer ML1, a first interlayer insulating layer ILD1, and a second metal layers ML2 may be sequentially disposed between the first pad electrode PAD1 and the first substrate SUBS1. The pattern of the second metal layer disposed on the gate insulating layer GI may include the first metal layer ML1. The pattern of the fourth metal layer disposed on the first interlayer insulating layer ILD1 may include the second metal layer ML2. The plurality of the insulating layers and the metal layers ML1, ML2 under the first pad electrodes PAD1 are not limited to those in FIG. 6.

A second substrate SUBS2 may be disposed on the rear surface of the first substrate SUBS1. A bonding layer BDL is disposed between the first substrate SUBS1 and the second substrate SUBS2. The bonding layer BDL is cured by different curing methods to bond the first substrate SUBS1 and the second substrate SUBS2. The bonding layer BDL may be disposed in only a portion of the area between the first substrate SUBS1 and the second substrate SUBS2, or it may be disposed in the entire area. The first substrate SUBS1 and the second substrate SUBS may be scribed and ground simultaneously so that the lateral surfaces of the first substrate SUBS1 and the second substrate SUBS2 do not have a step difference.

A plurality of second pad electrodes PAD2 may be disposed on the outermost rear surface of the second substrate SUBS2. The second pad electrodes PAD2 are electrically connected to the side wirings SRL and the first pad electrode PAD1 to transmit signals from circuit components disposed on the rear surface of the second substrate SUBS2 to the subpixels SP disposed on the upper surface of the first substrate SUBS1.

Each of the second pad electrodes PAD2 may have a multilayer structure of metal layers. For example, each of the second pad electrodes PAD2 may include a first pad metal layer PE2a, a second pad metal layer PE2b, and a third pad metal layer PE2c stacked on the outermost rear surface of the second substrate SUBS2. Each of the first and second pad metal layers PE2a, PE2b may be formed of copper (Cu), aluminum (Al), molybdenum (Mo), nickel (Ni), titanium (Ti), chromium (Cr), or a multilayer of metal layers. The third pad metal layer PE2c may be formed of a transparent conductive material such as indium tin oxide (ITO) or indium zinc oxide (IZO).

A second protective layer BCL may be disposed on the rear surface of the second substrate SUBS2. The second protective layer BCL may cover various wirings except for the second pad electrodes PAD2 on the rear surface of the second substrate SUBS2. The second protective layer BCL may be made of an organic insulating material, for example, a benzocyclobutene or acryl-based organic insulating material.

Circuit components such as a plurality of flexible films and PCBs may be disposed on the rear surface of the second substrate SUBS2. The output terminals of the flexible film are electrically connected to the second pad electrode PAD2, and the input terminals of the flexible film are electrically connected to the output terminals of the PCB. Accordingly, a signal or voltage output from a PCB may be transmitted to the subpixels SP disposed on the front surface of the first substrate SUBS1 via the flexible film, the second pad electrode PAD2, the side wiring SRL, the plurality of first pad electrodes PAD1, and the wiring connected to the first pad electrode PAD1.

The side wirings SRL electrically connect the first pad electrodes PAD1 and the second pad electrodes PAD2 across the side surfaces of the first substrate SUBS1 and the second substrate SUBS2. The side wirings SRL may be formed on the side surface of the substrates SUBS1, SUBS2 by a pad printing method using conductive inks, for example, the conductive inks including silver (Ag), copper (Cu), molybdenum (Mo), and chromium (Cr).

The side insulating layer SDI may cover the side wirings SRL formed on the outermost top, side, and rear surfaces of the bonded substrates SUBS1 and SUBS2. If the side wirings are metal, external light may be reflected from the side wirings or light emitted by the light emitting element ED may be reflected from the side wirings and be visible to the user. In order to improve image quality degradation due to the reflected light, the side insulating layer SDI may include a black material that absorbs external light. For example, the side insulating layer SDI may be formed on the outermost portion of the substrates SUBS1 and SUBS2 with a black ink that may be applied by a printing manner.

A seal SS may cover the side insulating layer SDI to protect the display panel 100 from external shock, moisture, oxygen, and the like. For example, the seal SS may be made of polyimide (PI), polyurethane, epoxy, or acryl-based insulating materials.

A functional film MF may cover the front surface of the display panel 100. The functional film MF may be one or more of a variety of functional films, such as an anti-scattering film, an anti-glare film, an anti-reflective film, a low-reflective film, an OLED transmittance controllable film for a luminance enhancement, a color difference compensation film, a polarizing plate, and the like. The anti-scattering film prevents or at least reduces substrate fragments or particles from scattering when the display panel 100 is damaged. The functional film MF may be removed by cutting the seal SS together with an outer portion of the seal SS along a cutting line overlapping the seal SS after the seal SS is widely adhered to the front surface of the first substrate SUBS1. As a result, the side surface exposed from the outermost portion of the functional film MF and the seal SS may form the side surface of the same plane without a step difference.

The display device according to an embodiment of the present disclosure may minimize or at least reduce a temperature difference for each area of the display panel 100 and make a temperature distribution of the display panel 100 uniform. To this end, the display device according to an embodiment of the present disclosure may present various embodiments of a module cover member disposed on the rear surface of the display panel 100. Here, the display device according to an embodiment of the present disclosure may be implemented as a single display device. In addition, since a large screen tiled display device TD may be implemented through a combination of the display devices according to a plurality of embodiments of the present invention, the display device according to embodiments of the present invention may be referred to as a display module.

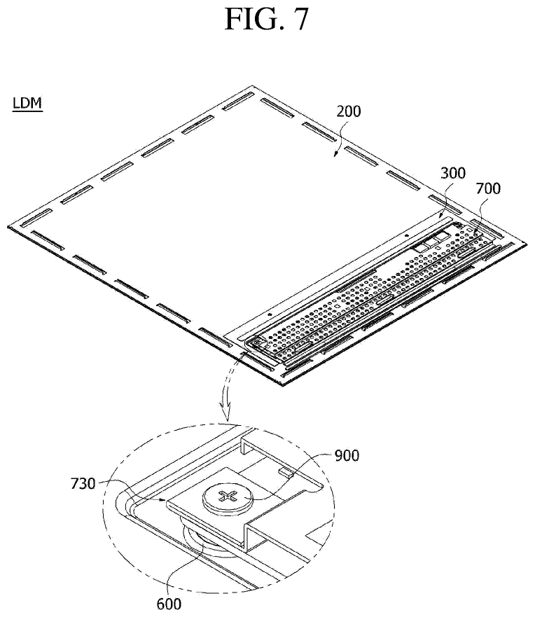

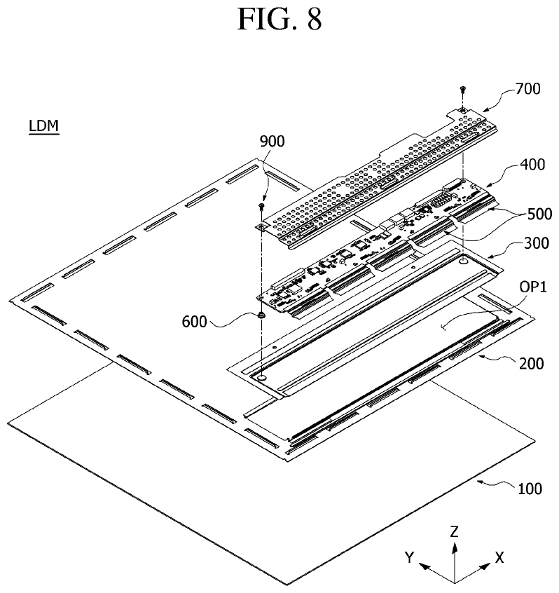

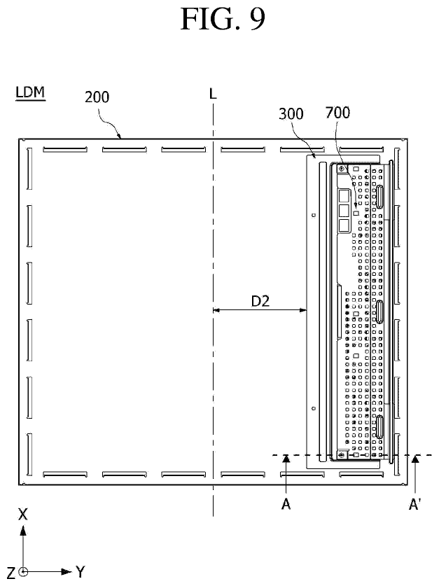

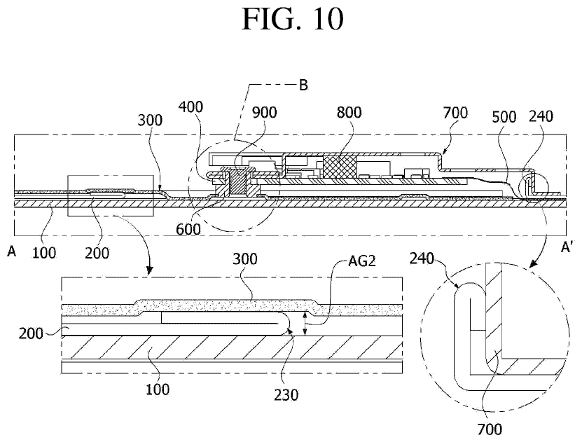

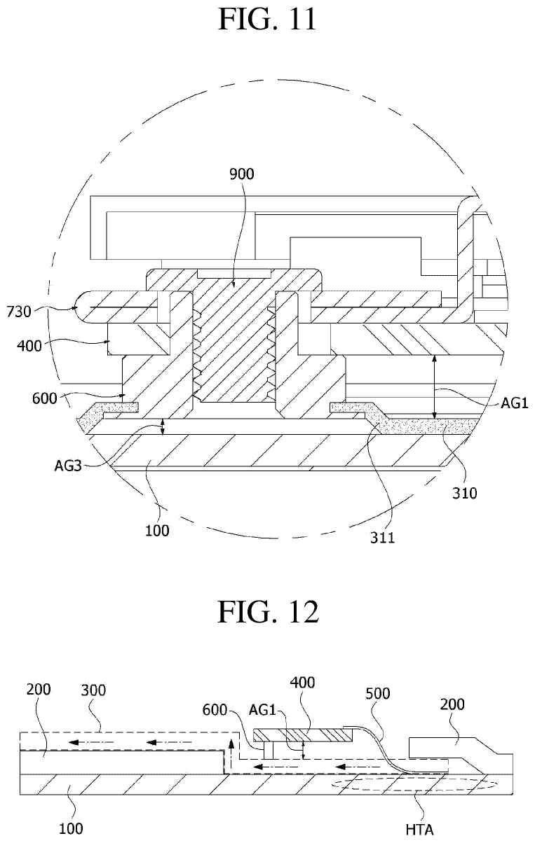

FIG. 7 is a perspective view showing a display device according to an embodiment of the present specification; FIG. 8 is an exploded perspective view showing a display device according to an embodiment of the present specification; FIG. 9 is a plan view showing a display device according to an embodiment of the present specification; FIG. 10 is a cross-sectional view showing a cross section taken along line A-A′ of FIG. 9 according to an embodiment of the present specification; FIG. 11 is a partial enlarged view of an area B of FIG. 10 according to an embodiment of the present specification; and FIG. 12 is a diagram showing a movement of heat in a display device according to an embodiment of the present specification. The arrows in FIG. 12 may indicate a movement of heat.

Referring to FIGS. 7 to 11, a display device LDM according to an embodiment may include: a display panel 100 including a front surface on which an image is implemented and a rear surface opposite to the front surface; a cover bottom 200 disposed on the rear surface of the display panel 100; a plate bottom 300 disposed in contact with the display panel 100 at an opening OP1 of the cover bottom 200, a circuit board 400; at least one flexible film 500 connecting the display panel 100 and the circuit board 400 through the opening OP1; and a pemnut 600 coupled to the plate bottom 300. Here, the display device LDM may use a stepped structure formed on the pemnut 600 to allow the circuit board 400 to be spaced apart from the plate bottom 300. Further, the flexible film 500 may be a chip on film (COF) on which an IC is mounted. In addition, the display device LDM according to an embodiment may include a cover shield 700 covering the circuit board 400. In addition, the display device LDM according to an embodiment may include a gasket 800 disposed for grounding between the circuit board 400 and the cover shield 700. In addition, the display device LDM according to an embodiment may include a fastening member 900 that fixes the circuit board 400 coupled to the pemnut 600.

Referring to FIG. 12, the flexible film 500 generates a considerable amount of heat due to the IC, and the second pad electrodes PAD2 made of metal and a plurality of wirings are densely disposed in one area of the rear surface of the display panel 100 to which the flexible film 500 is connected, so that a high heat source area HTA may be formed near the second pad electrodes PAD2.

The display device LDM according to the embodiment may radiate heat from the high heat source area HTA to the outside using a plate bottom 300, and at the same time, the circuit board 400 may disposed to be spaced apart from the plate bottom 300 using the pemnut 600 disposed to protrude from the plate bottom 300. Accordingly, the display device LDM according to the embodiment may minimize or at least reduce the influence on the high heat source area HTA by heat generated from the circuit board 400 by using the air gap AG1 formed between the plate bottom 300 and the circuit board 400. For example, the air gap AG1 and the air moving through the air gap AG1 may reduce the influence on the high heat source area HTA by heat of the circuit board 400. Here, the air gap AG1 formed in the area between the plate bottom 300 and the circuit board 400 may be referred to as a first air gap.

The display panel 100, the cover bottom 200, the plate bottom 300, and the cover shield 700 may form an outer appearance of the display device LDM according to the embodiment, and the module cover member may include a cover bottom 200, the plate bottom 300, and the cover shield 700.

The display panel 100 may be formed in a plate shape having a predetermined thickness and may include a front surface on which an image is displayed and a rear surface opposite to the front surface. Here, the rear surface may be one surface of the display panel 100 disposed on an upper portion based on the Z direction in the drawing (see FIG. 8). Further, the front surface of the display panel 100 may be referred to as a first panel surface, and the rear surface of the display panel 100 may be referred to as a second panel surface.

In addition, the display panel 100 may be electrically connected to the circuit board 400 using the flexible film 500.

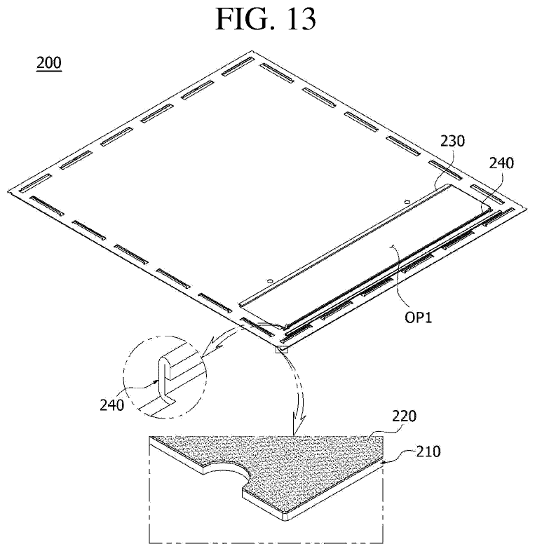

FIG. 13 is a perspective view showing a cover bottom disposed on a display device according to an embodiment of the present specification.

Referring to FIGS. 7 to 9 and FIG. 13, the cover bottom 200 may be formed in a shape corresponding to the rear surface of the display panel 100 and may support and protect the display panel 100.

In addition, the cover bottom 200 may include the opening OP1. Accordingly, the cover bottom 200 may be disposed on the rear surface of the display panel 100 to cover a portion of the rear surface of the display panel 100. In this case, the cover bottom 200 may include a rear surface and a front surface disposed to face the rear surface of the display panel 100. Here, the front surface of the cover bottom 200 may be referred to as a first cover surface, and the rear surface of the cover bottom 200 may be referred to as a second cover surface. In addition, the opening OP1 may be referred to as a first opening.

In addition, the cover bottom 200 may be fixed to the display panel 100 through an adhesive member. Here, the adhesive member may be made of an adhesive material such as foam tape, and may be disposed along the edge of the cover bottom 200. Accordingly, the cover bottom 200 may include a contact area that is in contact with the rear surface of the display panel 100 and a non-contact area that is not in contact with the rear surface of the display panel 100. In addition, heat of the display panel 100 may be dispersed through the contact area. To this end, the cover bottom 200 may be made of a material having rigidity and high thermal conductivity, for example, a metallic material such as iron (Fe), steel use stainless (SUS), or Invar.

In addition, a coating layer may be formed on the cover bottom 200 in response to damage caused by corrosion, chemical substances, or the like. However, the coating layer may be formed only on one side of the cover bottom 200 in consideration of the external aesthetics, productivity, radiant heat performance, etc. of the display device LDM.

Referring to FIG. 13, the cover bottom 200 may include a cover body 210 formed of a metallic material and a cover coating layer 220 coated on one side of the cover body 210.

In addition, the cover body 210 may be in contact with the rear surface of the display panel 100 and may be disposed on the rear surface of the display panel 100 to cover a portion of the rear surface of the display panel 100.

In addition, the cover body 210 may include a front surface disposed to face the rear surface of the display panel 100 and a rear surface opposite to the front surface. Accordingly, the cover body 210 may be fixed to the rear surface of the display panel 100 through an adhesive member disposed along the edge of the rear surface of the cover body 210. In this case, the cover body 210 may include a contact area that is in contact with the rear surface of the display panel 100 and a non-contact area that is not in contact with the rear surface of the display panel 100. Here, the front surface of the cover body 210 may be referred to as a first cover body surface, and the rear surface of the cover body 210 may be referred to as a second cover body surface.

In addition, the cover body 210 may be made of a metallic material having rigidity and a lower thermal conductivity than the thermal conductivity of the plate bottom 300.

The cover coating layer 220 may be disposed on the second cover body surface, which is the rear surface of the cover body 210. Accordingly, the first cover surface, which is the front surface of the cover bottom 200, may be formed by the cover body 210, and the second cover surface, which is the rear surface of the cover bottom 200, may be formed by the cover coating layer 220.

In addition, the cover coating layer 220 may be formed of an insulating material, and may be formed on the cover body 210 by electro-deposition coating, but is not necessarily limited thereto. Electro-deposition coating is one of the coating methods which immerses a workpiece as an anode or cathode in a water-soluble coating solution for electro-deposition, and electrically deposits a coating film on the surface of the workpiece through a direct current between the workpiece and its counter electrode.

In addition, the cover coating layer 220 may be provided in black according to a radiant heat principle of a black body. Accordingly, the emissivity of the cover coating layer 220 becomes 80% or more. Here, a black body is an object that completely absorbs radiation from all wavelength areas, meaning that it absorbs all incident radiation energy from the outside and surface reflection does not occur, that is, it has a radiation (absorption) efficiency of up to 1 with only re-radiation. In addition, the heat radiation emitted from the black body is referred to as black body radiation. In fact, it is difficult to manufacture a completely black body with a radiation efficiency of 1, but the emissivity may be increased to be close to that of the black body. For example, charcoal or soot is close to the black body.

Accordingly, the black cover coating layer 220 formed by electro-deposition coating increases film strength and is electro-deposited to be in close contact with the cover body 210 so that the cover bottom 200 may improve thermal conduction characteristics and heat emissivity. However, the thickness of the cover coating layer 220 may be within the range of 0.005 mm to 0.1 mm. If the thickness of the cover coating layer 220 is less than 0.005 mm, it is difficult to use the radiant heat principle of the black body, and if the thickness of the cover coating layer 220 exceeds 0.1 mm, the radiant heat effect may be reduced.

Meanwhile, the cover bottom 200 may include a first grounding structure for grounding with the plate bottom 300. However, since it there is difficulty in grounding between the cover bottom 200 and the plate bottom 300 due to the cover coating layer 220 of the cover bottom 200, the cover bottom 200 may implement a first grounding structure through a hemming structure. Here, hemming may be referred to as the process of folding and stacking the ends of plates.

Referring to FIGS. 10 and 13, the cover bottom 200 may include a first hemming portion 230 formed by cutting and bending a portion of an inner side end forming the opening OP1. The first hemming portion 230 may be disposed at an inner side end forming the opening OP1. Accordingly, the coated surfaces of the cover bottom 200 may be in contact with each other by the first hemming portion 230, and the uncoated surface of the cover bottom 200 may be in contact with the plate bottom 300. For example, even if the cover bottom 200 includes the cover coating layer 220, the first cover surface of the cover bottom 200 is exposed to the outside by the first hemming portion 230, and the exposed first cover surface may be in contact with the plate bottom 300 to implement the first grounding structure. In detail, the cover body 210 formed of a metallic material is exposed to the outside by the first hemming portion 230, and one surface of the exposed cover body 210 may be in contact with the plate bottom 300 to implement the first grounding structure. Here, the first hemming portion 230 may be referred to as a first grounding portion or a first cover hemming portion. In addition, the inner side may indicate a direction toward the center of the display panel.

In addition, the cover bottom 200 may include a second hemming portion 240 that contacts and supports one side end of the cover shield 700. In addition, the second hemming portion 240 may be formed by cutting and bending a portion of the outer side end of the cover bottom 200 forming the opening OP1. The second hemming portion 240 may be disposed at an outer side end forming the opening OP1. Accordingly, the second hemming portion 240 may be disposed to face the first hemming portion 230 with the opening OP1 interposed therebetween. In this case, the second hemming portion 240 may be formed to protrude toward the cover shield 700. Accordingly, the assembly of the cover shield 700 may be guided. Here, the outer side may represent a direction opposite to the inner side.

In addition, the second hemming portion 240 is formed in a hemming structure to implement a second grounding structure that may electrically connect the cover bottom 200 and the cover shield 700. For example, the uncoated surface of the cover bottom 200 may in contact with the cover shield 700 through the second hemming portion 240. Here, the second hemming portion 240 may be referred to as a second grounding portion or a second cover hemming portion, and may also be referred to a first protruding portion in consideration of being formed to protrude toward the cover shield 700.

Accordingly, the cover bottom 200 may be in contact with the plate bottom 300 and the cover shield 700 through the first hemming portion 230 and the second hemming portion 240 to implement the grounding structure. Here, the first hemming portion 230 may be formed by bending one side end of the cover body 210 on which the cover coating layer 220 is formed, and the second hemming portion 240 may be formed by bending the other side end of the cover body 210 on which the cover coating layer 220 is formed.

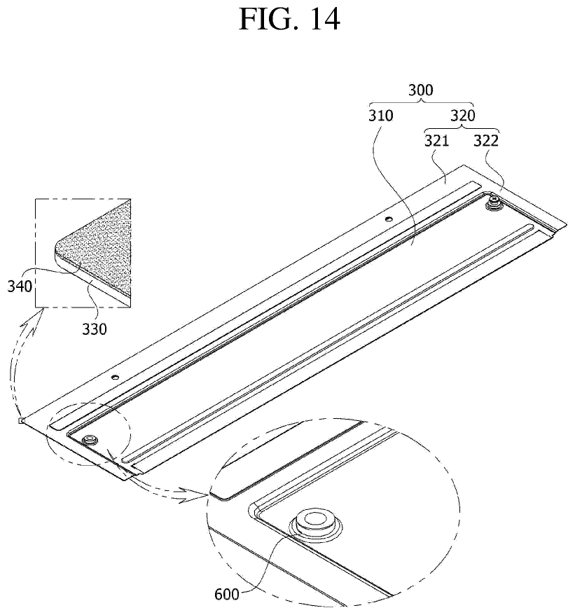

FIG. 14 is a perspective view showing an arrangement relationship between a plate bottom and a pemnut disposed in a display device according to an embodiment of the present specification.

Referring to FIGS. 7 to 11 and 14, the plate bottom 300 may be formed of a plate-shaped metallic material, and may be formed in a shape in which some areas are bent through a molding process such as a press. Here, the plate bottom 300 may be made of a metallic material having rigidity and a higher thermal conductivity than that of the cover bottom 200. For example, the plate bottom 300 may be formed of a material containing metallic materials such as aluminum (Al), copper (Cu), zinc (Zn), silver (Ag), gold (Au) and the like.

In addition, in consideration of the radiant heat, some areas of the plate bottom 300 may be in contact with the display panel 100 through the opening OP1, and some other areas may be in contact with the cover bottom 200. In this case, some other areas of the plate bottom 300 may be exposed to the outside to radiate heat from the high heat source area HTA.

In detail, the plate bottom 300 may include a first plate area 310 in contact with the display panel 100 through the opening OP1 of the cover bottom 200, and second plate area 320 bent and extended from the first plate area 310. In this case, the second plate area 320 may be exposed to the outside while contacting the cover bottom 200. Here, the first plate area 310 may include a hole into which the pemnut 600 is coupled.

The first plate area 310 may be arranged to overlap the display panel 100, and the second plate area 320 may be arranged to overlap the display panel 100 and the cover bottom 200. In this case, a partial area of the cover bottom 200 may be disposed between the display panel 100 and the second plate area 320. Accordingly, the heat emitted from the second plate area 320 does not directly affect the display panel 100. Furthermore, the influence of heat conducted from the second plate area 320 to the cover bottom 200 may be reduced by the cover coating layer 220 of the cover bottom 200 formed of an insulating material. Furthermore, the plate bottom 300 prevents direct contact between the display panel 100 and the circuit board 400 to radiate heat from the high heat source area HTA while minimizing or at least reducing the thermal effect between the display panel 100 and the circuit board 400.

The first plate area 310 is disposed in the opening OP1 and may be contact with the display panel 100 to dissipate heat from the high heat source area HTA. The first plate area 310 may include a first contact area in contact with the rear surface of the display panel 100 and a first non-contact area not in contact with the rear surface of the display panel 100.

The second plate area 320 extends from the first plate area 310 and may be disposed on the rear surface of the cover bottom 200. Accordingly, the second plate area 320 may be exposed to the outside. The second plate area 320 may include a second contact area that is in contact with the rear surface of the cover bottom 200 and a second non-contact area that is not in contact with the rear surface of the cover bottom 200.

Further, the second plate area 320 may include a first plate end area 321 extending in the Y direction from the first plate area 310 and a second plate end area 322 extending in the X direction from the first plate area 310.

A portion of the first plate end area 321 corresponding to the second non-contact area may be disposed to be spaced apart from and facing the rear surface of the display panel 100. Accordingly, an air gap AG2 may be formed between the second non-contact area and the rear surface of the display panel 100, and heat moving along the plate bottom 300 may be radiated before moving toward the first hemming portion 230 by air moving through the air gap AG2. In addition, the size of the air gap AG2 may be increased by the first hemming portion 230 disposed adjacent to the air gap AG2. Here, the air gap AG2 formed between the second non-contact area and the rear surface of the display panel 100 may be referred to as a second air gap. Accordingly, the second air gap and the air moving through the second air gap may reduce the influence on the display panel 100 by heat moving along the plate bottom 300.

Meanwhile, in order to prevent or minimize the influence on the center of the display panel 100 by heat moving along the plate bottom 300, the plate bottom 300 may be disposed to be spaced apart from the center of the display device LDM. As shown in FIG. 9, the plate bottom 300 may be disposed to be spaced apart from an imaginary line L passing the center of the display device LDM at a predetermined distance D2. Here, the imaginary line L is a line parallel to the X direction while passing the center of the display device LDM, and may be a line disposed parallel to the longitudinal direction of the plate bottom 300.

In detail, a first plate end area 321 or an end of the second plate area 320 of the plate bottom 300 may be disposed to be spaced apart from the imaginary line L passing the center of the display device LDM at a predetermined distance D2. Here, the distance D2 may be referred to as a second distance.

Accordingly, the second air gap and the second distance may allow the influence on the center of the display panel 100 by heat moving along the plate bottom 300 to be prevented or minimized. Accordingly, the display device LDM may make the heat distribution of the display panel 100 uniform.

Meanwhile, a coating layer may be formed on the plate bottom 300 in response to damage caused by corrosion, chemical substances, or the like. However, the coating layer may be formed only on one side of the plate bottom 300 in consideration of the external aesthetics, productivity, radiant heat performance, etc. of the display device LDM.

Referring to FIG. 14, the plate bottom 300 may include a plate body 330 formed of a metallic material and a plate coating layer 340 coated on one side of the plate body 330.

Further, the plate body 330 may be in contact with a portion of the rear surface of the display panel 100 and a portion of the rear surface of the cover bottom 200.

In addition, the plate body 330 may include a front surface disposed to face the rear surface of the display panel 100 and the rear surface of the cover bottom 200, and a rear surface opposite to the front surface. Accordingly, the plate body 330 may be fixed to the rear surface of the display panel 100 or the rear surface of the cover bottom 200 through an adhesive member. In this case, the plate body 330 may include a contact area that is in contact with the rear surface of the display panel 100 and the rear surface of the cover bottom 200, respectively, and a non-contact area that is not in contact with the rear surfaces. Here, the front surface of the plate body 330 may be referred to as a first plate body surface, and the rear surface of the plate body 330 may be referred to as a second plate body surface.

In addition, the plate body 330 may be made of a metallic material having rigidity and a higher thermal conductivity than that of the cover bottom 200.

The plate coating layer 340 may be disposed on the second plate body surface, which is the rear surface of the plate body 330. Accordingly, the first plate surface, which is the front surface of the plate bottom 300, may be formed by the plate body 330, and the second plate surface, which is the rear surface of the plate bottom 300, may be formed by the plate coating layer 340.

In addition, the plate coating layer 340 may be formed of an insulating material, and may be formed on the plate body 330 by electro-deposition coating, but is not necessarily limited thereto.

In addition, the plate coating layer 340 may be provided in black according to the radiant heat principle of a black body.

Accordingly, the black plate coating layer 340 formed by electro-deposition coating increases film strength and is electro-deposited to be in close contact with the plate body 330 so that the plate bottom 300 may improve thermal conduction characteristics and heat emissivity. However, the thickness of the plate coating layer 340 may be within the range of 0.005 to 0.1 mm. The thickness of the plate coating layer 340 may be about 15 μm in consideration of a press molding process and the plate body 330 formed of an aluminum material.

The circuit board 400 may be disposed to be spaced apart from the plate bottom 300. Accordingly, an air gap AG1 is formed in an area between the plate bottom 300 and the circuit board 400, and the air gap AG1 and the air moving through the air gap AG1 may reduce the influence on the display panel 100 by heat from the circuit board 400. Here, the circuit board 400 may be a printed circuit board (PCB).

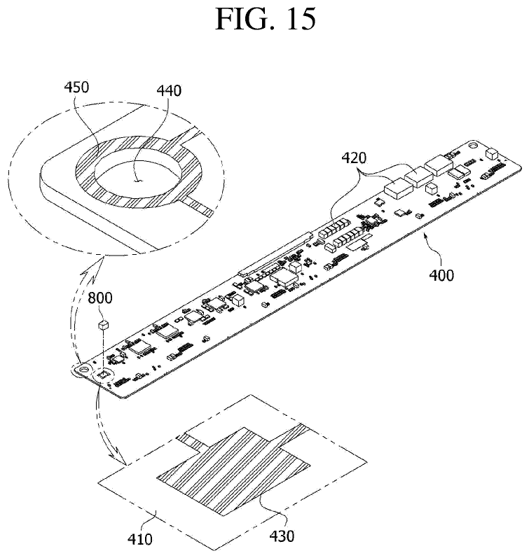

FIG. 15 is a perspective view showing a circuit board and gasket disposed in a display device according to an embodiment of the present specification.

Referring to FIG. 15, the circuit board 400 may include a plate-shaped circuit board body 410, circuit elements 420 and wirings (not shown) mounted on the circuit board body 410, a first ground pattern 430, a hole 440 provided for coupling with the pemnut 600, and a second ground pattern 450 formed around the hole 440. Here, the hole 440 of the circuit board 400 may be referred to as a substrate hole, a first through hole, or a first hole.

The circuit elements 420 may include various circuit elements for driving the display panel 100. For example, the circuit elements 420 may be elements used to generate various voltages such as a high-potential power source, a low-potential power source, and a reference power source, that is, power IC chips (or PMICs). The circuit elements 420 disposed on the circuit board body 410 may generate heat during driving. In particular, since a heat-generating temperature of the power IC chip and an inductor is high, the temperature of the area where the circuit board 400 is disposed in the display device LDM may be increased. Accordingly, the heat generated from the circuit board 400 may increase the temperature at the lower portion of the display panel 100, causing a temperature difference in the display panel 100. This temperature difference may serve as a major factor causing stains or color differences to be visible when an image is displayed in the pixels of the display panel 100. Accordingly, the display device LDM may reduce the influence on the display panel 100 by heat generated from the circuit elements 420 by separating the circuit board 400 from the display panel 100.

The first ground pattern 430 may be disposed on the circuit board body 410 to face the cover shield 700. Further, the first ground pattern 430 may be electrically connected to the circuit elements 420 through a wiring pattern. In addition, the first ground pattern 430 may overlap the gasket 800 so as to be in contact with the gasket 800.

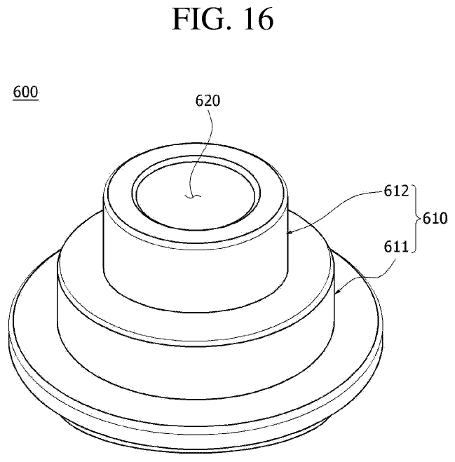

The hole 440 may be formed to penetrate the circuit board body 410 and may be disposed on the circuit board body 410 correspondingly to the pemnut 600. In this case, an inner diameter of the hole 440 may be smaller than an outer diameter of the first part 611 of the pemnut 600 having a stepped structure and may be larger than the outer diameter of the second part 612 (see FIG. 16). Accordingly, the front surface of the circuit board body 410 may be in contact with the first part 611 of the pemnut 600, and the second part 612 may be passed through the hole 440. Here, the front surface of the circuit board body 410 may be referred to as a first circuit board surface.

The second ground pattern 450 may be disposed on the circuit board body 410 to face the cover shield 700. Further, the second ground pattern 450 may be electrically connected to the circuit elements 420 through a wiring pattern. In addition, the second ground pattern 450 may be in contact with the first shield surface of the cover shield 700.

At least one flexible film 500 may electrically connect the display panel 100 and the circuit board 400. In detail, the flexible film 500 may connect the second pad electrodes PAD2 of the display panel 100 to the output terminals of the circuit board 400. In this case, the flexible film 500 may be bonded to the rear surface of the display panel 100 through an anisotropic conductive film (ACF). Here, the flexible film 500 may be a chip on film (COF) on which integrated circuits (ICs) of the data driver DD and/or the gate driver GD is mounted, but is not limited thereto.

The pemnut 600 is coupled to the hole of the plate bottom 300 and may be formed to protrude from the plate bottom 300. In this case, at least one pemnut 600 may be disposed in the first plate area 310 of the plate bottom 300. Further, the pemnut 600 may separate the circuit board 400 from the plate bottom 300 using a stepped structure. Accordingly, the display device LDM according to the embodiment may radiate heat from the high heat source area HTA to the outside using the plate bottom 300, and at the same time, the circuit board 400 may be disposed to be spaced apart from the plate bottom 300 using the pemnut 600 disposed to protrude from the plate bottom 300. Accordingly, the display device LDM according to the embodiment may minimize the influence on the high heat source area HTA by heat generated from the circuit board 400 by using the air gap AG1 formed between the plate bottom 300 and the circuit board 400.

Further, the pemnut 600 may be disposed on a bent portion 311 formed to be bent toward the circuit board 400 in the first plate area 310. In detail, the pemnut 600 may be coupled to the hole formed in the center of the bent portion 311. Accordingly, since the pemnut 600 may be disposed to be spaced apart from the display panel 100 at a predetermined distance, an air gap AG3 may be formed between the pemnut 600 and the rear surface of the display panel 100. Here, the air gap AG3 formed between the pemnut 600 and the rear surface of the display panel 100 may be referred to as a third air gap. Accordingly, the third air gap and the air moving through the third air gap may reduce the influence of heat on the display panel 100. In this case, the influence of heat may be caused by heat moving through the pemnut 600. Here, the bent portion 311 may be referred to as a plate protrusion.

Further, the pemnut 600 may be formed of a different material from the plate bottom 300, but is not necessarily limited thereto. When the pemnut 600 is formed of a different material from the plate bottom 300, the pemnut 600 may be formed of a material having a lower thermal conductivity than that of the plate bottom 300.

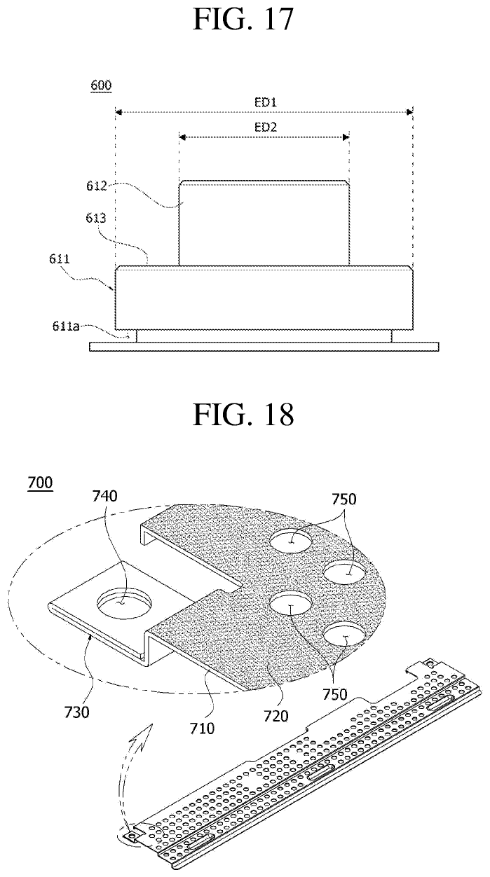

FIG. 16 is a perspective view showing a pemnut disposed in a display device according to an embodiment of the present specification, and FIG. 17 is a front view showing a pemnut disposed in a display device according to an embodiment of the present specification.

Referring to FIGS. 16 and 17, the pemnut 600 may include a nut 610 and a hole 620 penetrating the nut 610.

The nut 610 is disposed to be spaced apart from the rear surface of the display panel 100 and may be disposed to protrude from the plate bottom 300.

Further, the nut 610 may include a first part 611 and a second part 612 with different outer diameters, and a step surface 613.

The first part 611 may be formed to have a first outer diameter ED1. Further, the first outer diameter ED1 of the first part 611 may be formed to be larger than the second outer diameter ED2 of the second part 612.

In addition, the first part 611 may include a groove 611a concavely formed on the outer peripheral surface. Accordingly, the pemnut 600 may be coupled to the plate bottom 300 using the groove 611a. In detail, the end of the bent portion 311 of the plate bottom 300 may be disposed in the groove 611a. Accordingly, the pemnut 600 may be fixed to the plate bottom 300 and an air gap AG3 may be formed between the pemnut 600 and the rear surface of the display panel 100.

The second part 612 may be formed to protrude from the first part 611 to have a second outer diameter ED2. Further, the second outer diameter ED2 may be formed to be smaller than the first outer diameter ED1. Accordingly, the nut 610 may include the step surface 613 formed by the difference in outer diameter of the first part 611 and the second part 612.

In addition, the second part 612 may be passed through the hole 440 of the circuit board 400 and a first shield hole 740 (see FIG. 18) of the cover shield 700. Accordingly, the step surface 613 may be in contact with the front surface of the circuit board 400 to support the circuit board 400.

A fastening member 900 may be coupled to the hole 620. Accordingly, the circuit board 400 and the cover shield 700 coupled to the second part 612 may be fixed to the pemnut 600. Here, the hole 620 of the pemnut 600 may be referred to as a coupling hole.

The cover shield 700 may cover the circuit board 400 to protect the circuit board 400 from external impacts. As shown in FIG. 10, one side end of the cover shield 700 bent in an ‘L’ shape may engage the second hemming portion 240 of the cover bottom 200. By the engaging structure of the cover shield 700 and the cover bottom 200, the movement of the cover shield 700 may be restricted and the assembly position of the cover shield 700 may be guided.

FIG. 18 is a perspective view showing a cover shield disposed on a display device according to an embodiment of the present specification.

Referring to FIG. 18, the cover shield 700 may include a plate-shaped shield body 710 and a shield coating layer 720 coated on one surface of the shield body 710. In addition, the cover shield 700 may include a third hemming portion 730 formed by cutting and bending a portion of the shield body 710 coated with the shield coating layer 720, and a first shield hole 740 penetrating the third hemming portion 730. In addition, the cover shield 700 may include a plurality of second shield holes 750 penetrating the shield body 710 on which the shield coating layer 720 is coated. Here, one side of the cover shield 700 may be in contact with the circuit board 400 using the third hemming portion 730, and the other side may be in contact with the second hemming portion 240 of the cover bottom 200. The third hemming portion 730 may be referred to as a third grounding portion or a shield hemming portion.

The shield body 710 is disposed to face the circuit board 400 and may be disposed on the rear surface of the circuit board 400 to cover the circuit board 400. Accordingly, the shield body 710 may include a front surface disposed to face the rear surface of the circuit board 400 and a rear surface opposite to the front surface. In addition, the shield body 710 may be in contact the ground pattern of the circuit board 400 and the second hemming portion 240 of the cover bottom 200. Here, the front surface of the shield body 710 may be referred to as a first shield body surface, and the rear surface of the shield body 710 may be referred to as a second shield body surface.

In addition, the shield body 710 may be made of a material having a certain rigidity and high thermal conductivity, for example, a metallic material such as iron (Fe), steel use stainless (SUS), or Invar.

The cover shield 700 may include a coating layer formed on one surface only, like the cover bottom 200.

The shield coating layer 720 may be disposed on the second shield body surface, which is the rear surface of the shield body 710. Accordingly, the first shield surface, which is the front surface of the cover shield 700, may be formed by the shield body 710, and the second shield surface, which is the rear surface of the cover shield 700, may be formed by the shield coating layer 720.

Further, the shield coating layer 720 may be formed of an insulating material and may be formed on the shield body 710 by electro-deposition coating, but is not necessarily limited thereto.

In addition, the shield coating layer 720 may be provided in black according to the radiant heat principle of a black body. Accordingly, the emissivity of the shield coating layer 720 becomes 80% or more.

Accordingly, since the black shield coating layer 720 formed by electro-deposition coating increases film strength and is electro-deposited to be in close contact with the shield body 710, the cover shield 700 may improve thermal conduction characteristics and heat emissivity.

Meanwhile, one surface of the shield body 710 on which the shield coating layer 720 is not formed may be in contact with a ground pattern of the circuit board 400.

Referring to FIGS. 10, 11, and 18, the cover shield 700 may be in contact with the ground pattern of the circuit board 400 using the third hemming portion 730. In addition, the cover shield 700 may be in contact with the ground pattern of the circuit board 400 through a gasket 800.

The third hemming portion 730 may be formed by cutting and bending a portion of the end side of the cover shield 700. Here, the third hemming portion 730 uses a hemming structure so that the third hemming portion 730 may simultaneously in contact with the ground pattern of the circuit board 400 and a fastening member 900. In detail, one surface of the third hemming portion 730 disposed facing the circuit board 400 may be in contact with the second ground pattern 450 of the circuit board 400, and the other surface, which is the opposite surface of the one surface of the third hemming portion 730, may be in contact with the fastening member 900. Here, a bolt may be used as the fastening member 900, and the head of the bolt may be in contact with the other surface of the third hemming portion 730.

The first shield hole 740 may be formed in the third hemming portion 730 for coupling with the pemnut 600.

The first shield hole 740 may be formed to penetrate the third hemming portion 730 and may be disposed correspondingly to the pemnut 600. In this case, the inner diameter of the first shield hole 740 may be larger than the outer diameter of the second part 612 of the pemnut 600 having a stepped structure. Accordingly, the shield body 710 may be in contact with the second ground pattern 450 formed on the rear surface of the circuit board body 410, and the second part 612 may be passed through the first shield hole 740. Here, the rear surface of the circuit board body 410 may be referred to as a second circuit board surface. Further, the first shield hole 740 may be referred to as a second through hole or a second hole.

The cover shield 700 may include a plurality of second shield holes 750, as shown in FIG. 18. The second shield holes 750 may be evenly distributed on the cover shield 700 for radiant heat and air circulation. The second shield holes 750 allow heat or heated air generated in the circuit board 400 to be discharged to the outside through the cover shield 700. In the heat distribution of the circuit board 400, the cover shield 700 may be opened at a heat-generating portion having a high temperature, for example, an IC or an inductor. In this case, the high-temperature heat-generating portion of the circuit board 400 is exposed and not covered by the cover shield 700 so that the heat may be directly emitted to the outside. In another embodiment, as a result of measuring the heat distribution of the circuit board 400, the second shield holes 750 may be disposed in a portion of the cover shield 700 that overlap a heavily heated portion of the circuit board 400 so that a diameter of the second shield hole 750 formed in the cover shield 700 is increased, or a density of the second shield holes 750 is increased. Here, the second shield hole 750 may be referred to as a third through hole, a third hole, or a radiant heat hole.

The gasket 800 is disposed between the first ground pattern 430 of the circuit board 400 and the front surface of the cover shield 700, so that the first ground pattern 430 of the circuit board 400 and the cover shield 700 may be electrically connected. Here, the gasket 800 may be formed of a conductive material. Accordingly, the gasket 800 may implement a grounding structure connecting the circuit board 400 and the cover shield 700.

The gasket 800 may be formed in a structure having elastic restoring force, but is not necessarily limited thereto. For example, the gasket 800 may be formed to include a plurality of particles of a metallic material within a synthetic resin material having elastic restoring force.

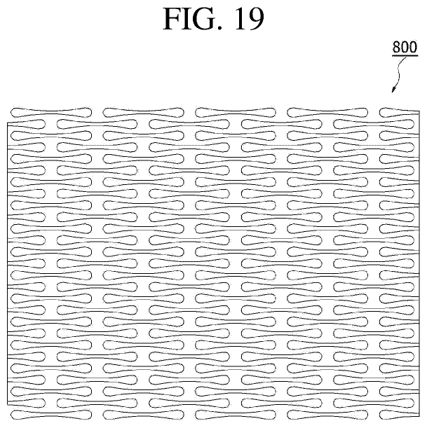

FIG. 19 is a diagram showing a cross section of a gasket disposed in a display device according to an embodiment of the present specification.

Referring to FIG. 19, the gasket 800 may be formed to have a net structure-shaped pattern and may be contracted or relaxed by a predetermined load. Accordingly, since the gasket 800 may have elastic restoring force, even if a predetermined load is applied to the cover shield 700, damage to the circuit board 400 due to the load may be prevented.

The fastening member 900 is coupled to the hole 620 of the pemnut 600 so as to the separation of the circuit board 400 and the cover shield 700 may be prevented and at the same time the cover shield 700 may be in close contact with the circuit board 400. In detail, a bolt may be used as the fastening member 900, and the head of the bolt may press the third hemming portion 730 so that the third hemming portion 730 is in close contact with the circuit board 400.

The display device LDM according to a plurality of embodiments may be implemented as a large-screen tiled display device through a combination. In this case, the display devices LDM according to a plurality of embodiments may be combined on a plane.

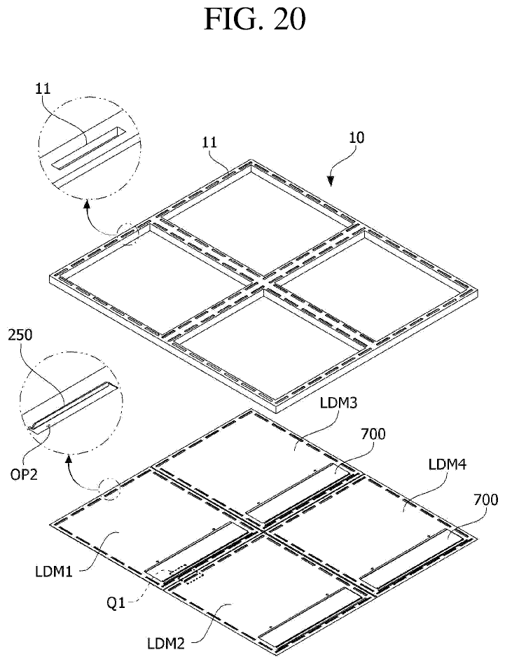

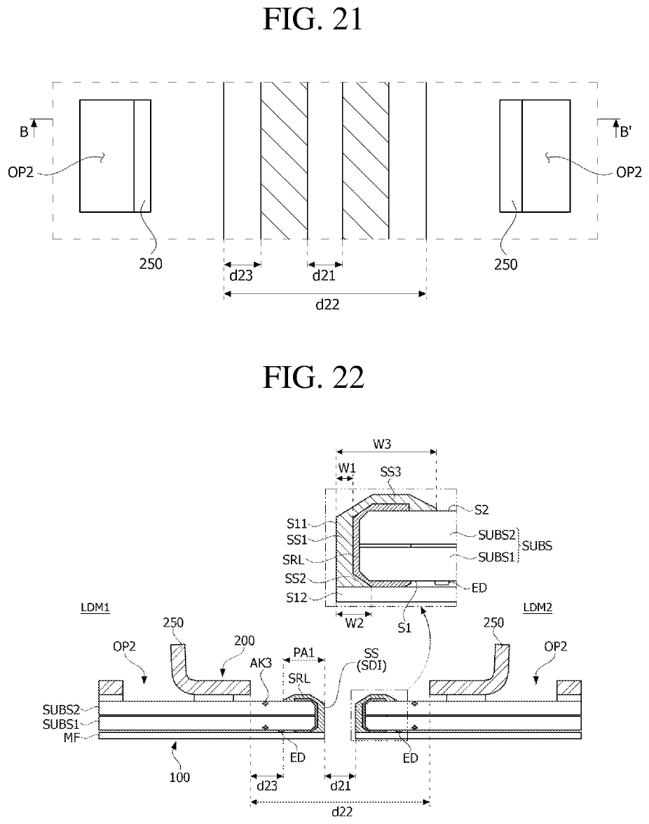

FIG. 20 is a perspective view showing a state in which display devices are fixed to a frame according to an embodiment of the present specification; FIG. 21 is a partially enlarged view of an area Q1 in FIG. 20 according to an embodiment of the present specification; and FIG. 22 is a cross-sectional view showing a cross section taken along line B-B′ of FIG. 21 according to an embodiment of the present specification.

Referring to FIG. 20, the display devices LDM according to a plurality of embodiments may be respectively coupled to a frame 10 and implemented as a large screen tiled display device. In FIG. 20, four display devices LDM1, LDM2, LDM3, and LDM4 are shown coupled to the frame 10, but the number of display devices LDM is not particularly limited.

The display device LDM according to the embodiment may further include a plurality of protrusions 250. The protrusion 250 may be formed by cutting and bending a portion of the cover bottom 200. Accordingly, an opening OP2 may be formed. Here, the protrusion 250 may be referred to as a second protrusion, and the opening OP2 may be referred to as a second opening.

The plurality of protrusions 250 disposed on each of the plurality of display devices LDM may be inserted into the insertion holes 11 of the frame 10, respectively. Thereafter, the protrusion 250 is fixed to the insertion hole 11 so that a plurality of display devices LDM may be fixed to the frame 10.

According to the embodiment, since the plurality of display devices LDMs are combined with the frame 10 to form a tiled display module, a distance between the plurality of display devices LDMs may need to be kept constant for a uniform image, and a flattening operation may be required to prevent a step difference from occurring.

Referring to FIGS. 21 and 22, the display devices may be disposed to be spaced apart at a predetermined distance when coupled to the frame 10. When the plurality of display devices are fixed to the frame 10 without a distance, if the step difference occurs due to an assembly tolerance, a problem in which the boundaries of the plurality of display devices are visible may occur. Accordingly, in order to configure the integrated tiled display device, the plurality of display devices LDM disposed adjacent to each other may be spaced apart at a predetermined distance.

A first distance d21 of the plurality of display devices LDM may be 1 μm to 200 μm. If this distance is satisfied, the problem of interference due to tolerance or thermal deformation may be resolved and the seam area may not be visible. However, the first distance d21 is not necessarily limited thereto and may be adjusted in various ways depending on the structure or size of the display panel.

As described above, the first pad electrodes may be disposed on the outermost portion of one surface S1 of the display panel 100, and the second pad electrodes may be disposed on the outermost portion of the other surface S2. The first pad electrode and the second pad electrode may be electrically connected by a side wiring SRL. A seal SS may be formed on the side wiring SRL. The seal SS may include black ink or an organic/inorganic material layer.

A functional film MF attached to the substrate SUBS may have a side surface parallel to the side surface of the seal SS. That is, the side surface S12 of the functional film MF and the side surface S11 of the seal SS may be disposed on the same plane. Accordingly, the first distance d21 between the seals SS and the distance d21 between the functional films MF in the two neighboring display devices LDM1 and LDM2 may be the same.

The seal SS may include a first area SS1 formed on the side surface of the substrate SUBS, a second area SS2 extending to one surface S1 of the substrate SUBS, and a third area SS3 connected to the other surface S2 of the substrate SUBS. In this case, the width W3 of the third area SS3 may be larger than the width W2 of the second area SS2, and the width W2 of the second area SS2 may be larger than the width W1 of the first area SS1. The second area SS2 may not partially cover the side wiring SRL formed on one surface of the substrate SUBS. This is because the seal SS is formed after attaching the functional film MF to one surface of the substrate SUBS on which the side wiring SRL is formed. The third area SS3 of the seal SS may be sufficiently wide to cover the side wiring SRL exposed on the other surface of the substrate SUBS.

The area of the cover bottom 200 may be smaller than the area of the display panel 100. Accordingly, the cover bottom 200 may not cover the seal SS formed on the side surface of the display panel 100. The cover bottom 200 may be spaced apart from the seal SS at a predetermined interval. This is because if the cover bottom 200 is designed to have the same area as the display panel 100, interference with a neighboring display device LDM may occur if assembly tolerances, etc. occur.

Accordingly, the second distance d22 where the cover bottom 200 is separated from the neighboring display devices LDM1 and LDM2 may be larger than the first distance d21 where the seal SS is separated from the neighboring display devices LDM1 and LDM2.

According to this configuration, the cover bottom 200 may expose an alignment key AK3 for arranging the display panel 100 in a correct position on a jig. Accordingly, the alignment key AK3 may be disposed in a spacing space corresponding to the third distance d23 between the cover bottom 200 and the seal SS. However, it is not necessarily limited to this, and the cover bottom 200 may extend to cover the seal SS. In this case, a hole may be formed in the cover bottom 200 to expose the alignment key AK3.

The cover bottom 200 may include a plurality of protrusions 250 for coupling with the frame 10. The protrusion 250 may be formed by cutting and then bending a portion of the cover bottom 200. Accordingly, the protrusion 250 may be formed on one side of the opening OP2 formed by cutting. However, it is not necessarily limited to this, and a separate protrusion may be coupled to the cover bottom 200. That is, various known methods may be applied to the configuration of forming the protrusion 250.

The embodiments of the present disclosure described above are briefly described as follows.

A display device according to embodiments of the present specification includes: a display panel; a cover bottom disposed on a rear surface of the display panel; a plate bottom disposed in contact with the display panel at an opening of the cover bottom; a circuit board; a flexible film connecting the display panel and the circuit board through the opening; and a cover shield covering the circuit board, wherein the cover bottom includes a first grounding portion in contact with the plate bottom and a second grounding portion in contact with the cover shield, and the cover shield includes a third grounding portion in contact with the circuit board, and wherein at least one of the first grounding portion, the second grounding portion, and the third grounding portion is formed in a hemming structure.

A display device according to embodiments of the present specification includes: a display panel; a cover bottom disposed on a rear surface of the display panel; a plate bottom disposed in contact with the display panel at an opening of the cover bottom; a circuit board; and a flexible film connecting the display panel and the circuit board through the opening, wherein the cover bottom includes a cover body disposed to face the display panel, a cover coating layer formed on a rear surface of the cover body, and a first hemming portion formed by bending one side end of the cover body on which the cover coating layer is formed, and wherein the first hemming portion is in contact with a front surface of the plate bottom.

In the display device according to embodiments of the present specification, the first hemming portion may be disposed at an inner side end forming the opening.

The display device according to embodiments of the present specification further includes a cover shield covering the circuit board, wherein the cover bottom may include a second hemming portion formed by bending the other side end of the cover body on which the cover coating layer is formed, and an uncoated surface of the cover bottom may be in contact with the cover shield through the second hemming portion.

In the display device according to embodiments of the present specification, the second hemming portion may be disposed at an outer side end forming the opening.

In the display device according to embodiments of the present specification, the plate bottom may be made of a different material from the cover bottom, and the material of the plate bottom may have a higher thermal conductivity than the material of the cover bottom.

In the display device according to embodiments of the present specification, the plate bottom may include a first plate area in contact with the display panel through the opening, and a second plate area bent and extended from the first plate area, and the second plate area may include a contact area and a non-contact area depending on whether the second plate area is in contact with a rear surface of the cover bottom, and an air gap may be formed between the non-contact area of the second plate area and the rear surface of the display panel.

In the display device according to embodiments of the present specification, the plate bottom may include a first plate area in contact with the display panel through the opening, and a second plate area bent and extended from the first plate area, and an end of the second plate area is spaced apart from an imaginary line passing the center of the display panel at a predetermined distance.

In the display device according to embodiments of the present specification, the plate bottom may include a plate body made of a metallic material and in contact with the rear surface of the display panel, and a plate coating layer coated on one surface of the plate body, wherein the plate coating layer formed of an insulating material may be formed in black.

The display device according to embodiments of the present specification further includes at least one pemnut disposed on the plate bottom to protrude toward the circuit board, wherein the circuit board may be spaced apart from the plate bottom by the pemnut.

In the display device according to embodiments of the present specification, the pemnut may include a first part, a second part protruding from the first part, and a step surface, and a first outer diameter, which is the outer diameter of the first part, is larger than a second outer diameter, which is the outer diameter of the second part, wherein the second part may be passed through a hole of the circuit board, and the step surface may be in contact with the circuit board.

The display device according to embodiments of the present specification further includes a cover shield covering the circuit board and a fastening member coupled to a hole of the pemnut, wherein the second part may be passed through a first shield hole of the cover shield and the cover shield may be in close contact with the circuit board by the fastening member.

In the display device according to embodiments of the present specification, the cover shield may include a shield body disposed to face the circuit board, a shield coating layer formed on the rear surface of the shield body, and a third hemming portion formed by bending one side end of the shield body on which the shield coating layer is formed, wherein one surface of the third hemming portion may be in contact with the circuit board, and the other surface of the third hemming portion may be in contact with the fastening member.

In the display device according to embodiments of the present specification, the pemnut may be spaced apart from the rear surface of the display panel.

The display device according to embodiments of the present specification includes: a display panel; a cover bottom disposed on a rear surface of the display panel; a plate bottom disposed in contact with the display panel at an opening of the cover bottom; at least one pemnut disposed on the plate bottom to protrude toward the circuit board; a circuit board spaced apart from the plate bottom by the pemnut; a flexible film connecting the display panel and the circuit board through the opening; and a cover shield covering the circuit board, wherein the cover shield may include a shield body disposed to face the circuit board, a shield coating layer formed on a rear surface of the shield body, and a third hemming portion formed by bending one side end of the shield body on which the shield coating layer is formed, and one surface of the third hemming portion may be in contact with the circuit board.

In the display device according to embodiments of the present specification, the display device may further include a fastening member coupled to the pemnut, and the cover shield may be in close contact with the circuit board by the fastening member.

In the display device according to embodiments of the present specification, the other surface of the third hemming portion may be contact with the fastening member.

The display device according to embodiments of the present specification may further include a cover shield that covers the circuit board, and a plurality of holes may be formed in the cover shield.

In the display device according to embodiments of the present specification, the display device may further include a gasket disposed between the circuit board and the cover shield, and the gasket may connect a ground pattern of the circuit board and the cover shield.

In the display device according to embodiments of the present specification, the gasket may be formed in a net structure having elastic restoring force.

In the display device according to embodiments of the present specification, an IC may be mounted on a flexible film connected to second pad electrodes of the display panel.

The objects to be achieved by the present disclosure, the means for achieving the objects, and effects of the present disclosure described above do not specify essential features of the claims, and thus, the scope of the claims is not limited to the detailed description of the present disclosure.

Although the embodiments of the present disclosure have been described in more detail with reference to the accompanying drawings, the present disclosure is not limited thereto and may be embodied in many different forms without departing from the technical concept of the present disclosure. Therefore, the embodiments disclosed in the present disclosure are provided for illustrative purposes only and are not intended to limit the technical concept of the present disclosure. The scope of the technical concept of the present disclosure is not limited thereto. Therefore, it should be understood that the above-described embodiments are illustrative in all aspects and do not limit the present disclosure.

### DESCRIPTION OF REFERENCE NUMERALS

| | |
|---|---|
| 100: | Display panel |
| 200: | Cover bottom |
| 300: | Plate bottom |
| 400: | Circuit board |
| 500: | Flexible film |
| 600: | Pemnut |
| 700: | Cover shield |
| 800: | Gasket |
| 900: | Fastening member |

What is claimed is:

1. A display device comprising:
a display panel;
a cover bottom on a rear surface of the display panel;
a plate bottom in contact with the display panel at an opening of the cover bottom;
a circuit board;
a flexible film connecting the display panel and the circuit board through the opening; and
a cover shield covering the circuit board,
wherein the cover bottom includes a first grounding portion in contact with the plate bottom and a second grounding portion in contact with the cover shield,
wherein the cover shield includes a third grounding portion in contact with the circuit board, and
wherein at least one of the first grounding portion, the second grounding portion, and the third grounding portion has a hemming structure.

2. The display device of claim 1, wherein the cover shield includes a plate-shaped shield body and a shield coating layer coated on one surface of the plate-shaped shield body, and
wherein the third grounding portion is a cut and bent portion of the plate-shaped shield body coated with the shield coating layer.

3. The display device of claim 2, wherein one surface of the plate-shaped shield body on which the shield coating layer is not in contact with a ground pattern of the circuit board.

4. A display device comprising:
a display panel;
a cover bottom on a rear surface of the display panel;
a plate bottom in contact with the display panel at an opening of the cover bottom;
a circuit board; and
a flexible film connecting the display panel and the circuit board through the opening,
wherein the cover bottom includes a cover body that faces the display panel, a cover coating layer on a rear surface of the cover body, and a first hemming portion including a bent one side end of the cover body on which the cover coating layer is formed, and the first hemming portion is in contact with a front surface of the plate bottom.

5. The display device of claim 4, wherein the first hemming portion is at an inner side end forming the opening.

6. The display device of claim 5, further comprising:
a cover shield covering the circuit board,
wherein the cover bottom includes a second hemming portion including a bent other side end of the cover body on which the cover coating layer is formed, and an uncoated surface of the cover bottom is in contact with the cover shield through the second hemming portion.

7. The display device of claim 6, wherein the second hemming portion is at an outer side end forming the opening.

8. The display device of claim 4, wherein a material of the plate bottom is different from a material of the cover bottom, and the material of the plate bottom has a higher thermal conductivity than the material of the cover bottom.

9. The display device of claim 8, wherein the plate bottom includes a first plate area in contact with the display panel through the opening, and a second plate area bent and extended from the first plate area,
the second plate area includes a contact area and a non-contact area depending on whether the second plate area is in contact with a rear surface of the cover bottom, and
an air gap is between the non-contact area of the second plate area and the rear surface of the display panel.

10. The display device of claim 8, wherein the plate bottom includes a first plate area in contact with the display panel through the opening, and a second plate area bent and extended from the first plate area, and an end of the second plate area is spaced apart from an imaginary line passing a center of the display panel at a predetermined distance.

11. The display device of claim 8, wherein the plate bottom includes a plate body made of a metallic material to be in contact with the rear surface of the display panel, and a plate coating layer coated on one surface of the plate body, and the plate coating layer includes an insulating material and is black.

12. The display device of claim 4, further comprising:
at least one pemnut on the plate bottom and protrudes toward the circuit board, wherein the circuit board is spaced apart from the plate bottom by the pemnut.

13. The display device of claim 12, wherein the pemnut includes a first part, a second part protruding from the first part, and a step surface, and
a first outer diameter, which is an outer diameter of the first part, is larger than a second outer diameter, which is an outer diameter of the second part, and
the second part is passed through a hole of the circuit board, and the step surface is in contact with the circuit board.

14. The display device of claim 13, further comprising:
a cover shield covering the circuit board and a fastening member coupled to a hole of the pemnut,
wherein the second part passes through a first shield hole of the cover shield, and
the cover shield is in contact with the circuit board by the fastening member.

15. The display device of claim 14, wherein the cover shield includes a shield body that faces the circuit board, a shield coating layer on the rear surface of the shield body, and a third hemming portion including a bent one side end of the shield body on which the shield coating layer is formed, and
one surface of the third hemming portion is in contact with the circuit board, and another surface of the third hemming portion is in contact with the fastening member.

16. The display device of claim 12, wherein the pemnut is spaced apart from the rear surface of the display panel.

17. The display device of claim 4, wherein a thickness of the cover coating layer is within a range of 0.005 mm to 0.1 mm.

18. The display device of claim 14, wherein the first shield hole is disposed correspondingly to the pemnut, and
wherein the cover shield further includes a plurality of second shield holes evenly distributed on the cover shield.

19. The display device of claim 13, wherein the first part includes a groove concavely formed on an outer peripheral surface, and the pemnut is coupled to the plate bottom using the groove.

20. A display device comprising:
a display panel;
a cover bottom on a rear surface of the display panel;
a plate bottom in contact with the display panel at an opening of the cover bottom;
at least one pemnut that protrudes from the plate bottom;
a circuit board spaced apart from the plate bottom by the pemnut;
a flexible film connecting the display panel and the circuit board through the opening; and
a cover shield covering the circuit board,
wherein the cover shield includes a shield body that faces the circuit board, a shield coating layer on a rear surface of the shield body, and a third hemming portion including a bent one side end of the shield body on which the shield coating layer is formed, and
one surface of the third hemming portion is in contact with the circuit board.

21. The display device of claim 20, further comprising:
a fastening member coupled to the pemnut, wherein the cover shield is in contact with the circuit board by the fastening member.

22. The display device of claim 21, wherein another surface of the third hemming portion is contact with the fastening member.

23. The display device of claim 21, wherein the pemnut includes a first part, a second part protruding from the first part, and a step surface,
a first outer diameter, which is an outer diameter of the first part, is larger than a second outer diameter, which is an outer diameter of the second part,
the second part is passed through a hole of the circuit board and a hole in the third hemming portion, and
the step surface is in contact with the circuit board.

24. The display device of claim 20, wherein the plate bottom includes a plate body made of a metallic material and is in contact with the rear surface of the display panel, and a plate coating layer coated on one surface of the plate body, and
the plate coating layer including an insulating material and is black.

25. The display device of claim 20, wherein a material of the plate bottom is different from a material of the cover bottom, and the material of the plate bottom has a higher thermal conductivity than the material of the cover bottom.

26. The display device of claim 20, wherein the plate bottom includes a first plate area in contact with the display panel through the opening, and a second plate area bent and extended from the first plate area,
the second plate area includes a contact area and a non-contact area depending on whether the second plate area is in contact with a rear surface of the cover bottom, and
an air gap is between the non-contact area of the second plate area and the rear surface of the display panel.

27. The display device of claim 25, wherein the plate bottom includes a first plate area in contact with the display panel through the opening, and a second plate area bent and extended from the first plate area, and an end of the second plate area is spaced apart from an imaginary line passing a center of the display panel at a predetermined distance.

28. The display device of claim 20, wherein the pemnut is spaced apart from the rear surface of the display panel.

29. The display device of claim 23, wherein the circuit board includes a plate-shaped circuit board body, circuit elements and wirings mounted on the plate-shaped circuit board body, a first ground pattern, the hole provided for coupling with the pemnut, and a second ground pattern formed around the hole.

30. The display device of claim 29, further comprising:
a gasket between the circuit board and the cover shield, wherein the first ground pattern is on the plate-shaped circuit board body and faces the cover shield, and the first ground pattern overlaps the gasket and is in contact with the gasket,
wherein the second ground pattern is in contact with a first shield surface of the cover shield.

31. The display device of claim 30, wherein the gasket has a net structure having elastic restoring force.

32. The display device of claim 30, wherein the gasket includes a plurality of particles of a metallic material within a synthetic resin material having elastic restoring force.
